(19) United States
(12) Patent Application Publication
(10) Pub. No.: US 2022/0085476 A1
(43) Pub. Date: Mar. 17, 2022

(54) MULTI-POLE RF FILTERS

(71) Applicants: Huan WANG, Richardson, TX (US); Michael BROBSTON, Allen, TX (US); Sammit PATEL, Dallas, TX (US); Charles Darwin BERNARDO, Port Barrington, IL (US); CommScope Italy S.r.l., Agrate Brianza (IT)

(72) Inventors: Huan Wang, Richardson, TX (US); Michael Brobston, Allen, TX (US); Sammit Patel, Dallas, TX (US); Charles Darwin Bernardo, Port Barrington, IL (US)

(21) Appl. No.: 17/425,633

(22) PCT Filed: Nov. 8, 2019
(86) PCT No.: PCT/US19/60483

§ 371 Date: Jul. 23, 2021

Related U.S. Application Data
(60) Provisional application No. 62/796,752, filed on Jan. 25, 2019.

(51) Int. Cl. H01P 1/205; H01P 1/213; H05K 1/14

(52) U.S. Cl. CPC H01P 1/2056; H01P 1/2135; H05K 2201/1006; H05K 2201/09063; H05K 1/144

(57) ABSTRACT

Multi-pole filters are provided herein. A multi-pole filter includes a substrate having a first resonator layer on a first side of the substrate and a second resonator layer that is electrically coupled to the first resonator layer and is on a second side of the substrate that is opposite the first side of the substrate.

### CROSS-REFERENCE TO RELATED APPLICATION

The present application claims priority to U.S. Provisional Patent Application No. 62/796,752, filed Jan. 25, 2019, the entire content of which is incorporated herein by reference.

### FIELD

The present disclosure relates to Radio Frequency (RF) filters and, in particular, to multi-pole RF filters.

### BACKGROUND

Two examples of RF filters are Printed Circuit Board (PCB) filters and fully-mechanical (e.g., die-cast) filters. These two types of RF filters can both have tradeoffs. For example, fully-mechanical RF filters, such as fully-mechanical diplexers, can be bulky and expensive, but beneficially provide a high Q-factor and can handle high power signals (i.e., provide high performance). PCB diplexers, on the other hand, can be compact, lightweight, and low cost, but provide a low Q-factor and can only handle low power signals (i.e., provide low performance). As an example, rough surfaces of resonators in PCB structures may cause passive intermodulation (PIM) issues that degrade performance. Moreover, fabrication tolerance of critical dimensions, such as the size of resonators and the spacing between resonators, is typically greater in fully-mechanical structures than in PCB structures.

### SUMMARY

A multi-pole filter, according to some embodiments herein, may include a substrate. The multi-pole filter may include first and second resonators on a first side of the substrate. The multi-pole filter may include third and fourth resonators on a second side of the substrate that is opposite the first side of the substrate. The multi-pole filter may include a first vertical connection that extends vertically from the first side of the substrate to the second side of the substrate, to electrically connect the first resonator to the third resonator. The multi-pole filter may include a second vertical connection that extends vertically from the first side of the substrate to the second side of the substrate, to electrically connect the second resonator to the fourth resonator. Moreover, the multi-pole filter may include an opening in the substrate between the first resonator and the second resonator. The first vertical connection may include metal plating that extends vertically on a sidewall of the opening to electrically connect the first resonator to the third resonator.

In some embodiments, the opening may extend through the substrate between respective first portions of the first and second resonators that are narrower than respective second portions of the first and second resonators, and between respective first portions of the third and fourth resonators that are narrower than respective second portions of the third and fourth resonators. The multi-pole filter may include a first metallized via that electrically connects the first resonator and the third resonator to each other. Moreover, the second vertical connection may include a second metallized via that electrically connects the second resonator and the fourth resonator to each other.

According to some embodiments, the multi-pole filter may include a first metal cover over the first and second resonators on the first side of the substrate. Moreover, the multi-pole filter may include a second metal cover over the third and fourth resonators on the second side of the substrate.

In some embodiments, the substrate may be a substrate of a first printed circuit board (PCB). Moreover, the multi-pole filter may include second and third PCBs on the first side of the substrate of the first PCB, and fourth and fifth PCBs on the second side of the substrate of the first PCB.

According to some embodiments, the second PCB may be between the first and third PCBs and may include a first opening. Moreover, the fourth PCB may be between the first and fifth PCBs and may include a second opening, and the second and fourth PCBs each may include metallized sidewalls.

In some embodiments, the multi-pole filter may include a screw that connects the second and third PCBs to each other.

According to some embodiments, the multi-pole filter may include a pre-preg that connects the second and third PCBs to each other. Moreover, the multi-pole filter may include a first metallized via that electrically connects the first resonator and the third resonator to each other. The second vertical connection may include a second metallized via. The multi-pole filter may include a third metallized via that electrically connects the first and second PCBs to each other. The second PCB may include an opening that extends to an outer edge of the second PCB.

In some embodiments, the multi-pole filter may include a fifth resonator on the first side of the substrate. The first, second, and fifth resonators may be tapered toward respective first, second, and third openings in the substrate. Moreover, the fifth resonator may include different first, second, and third widths.

According to some embodiments, the first and second resonators may be among a first plurality of resonators on the first side of the substrate. The first plurality of resonators may include a pair of digital resonators and a pair of interdigital resonators. The third and fourth resonators may be among a second plurality of resonators on the second side of the substrate. Moreover, a first and a second of the pair of digital resonators may be connected to each other by a metal connection line.

In some embodiments, a widest width of the first of the pair of digital resonators may be wider than a widest width of the second of the pair of digital resonators. Moreover, the multi-pole filter may include a third plurality of resonators on the first side of the substrate, and the first and third pluralities of resonators may be first and second filters, respectively, of a diplexer. The multi-pole filter may include a metal junction that connects the first and second filters to a common port. Alternatively, the multi-pole filter may include a common resonator that is coupled to a common port of the first and second filters.

According to some embodiments, the multi-pole filter may include a solder mask that is between the first resonator and the second resonator. Additionally or alternatively, the sidewall of the opening may include a non-plated through-hole that is free of the metal plating. Moreover, an embedded resonator may be within the second resonator.

In some embodiments, the first resonator may be wider than the second resonator and wider than the third resonator. Moreover, an entirety of the second resonator may overlap the fourth resonator, and a portion of the first resonator may overlap the fourth resonator.

A multi-pole filter, according to some embodiments, may include metal plating that extends on a sidewall of an opening in a substrate to electrically connect a first resonator layer on a first side of the substrate to a second resonator layer on a second side of the substrate that is opposite the first side of the substrate. Moreover, the multi-pole filter may include a metallized via that extends through the substrate to electrically connect the first resonator layer to the second resonator layer. Alternatively, the first resonator layer and the second resonator layer may be free of any metallized via.

In some embodiments, the substrate may be a plastic substrate, and the first and second resonator layers may be stamped metal.

According to some embodiments, the multi-pole filter may include a double-sided printed circuit board (PCB) that includes the substrate and the first and second resonator layers. Moreover, the double-sided PCB may be a double-sided diplexer PCB. Additionally or alternatively, the multi-pole filter may include a phase shifter on the substrate.

A multi-pole filter, according to some embodiments, may include a double-sided printed circuit board (PCB) diplexer. The double-sided PCB diplexer may include a substrate. The double-sided PCB diplexer may include a first resonator layer including first and second filters on a first side of the substrate. The double-sided PCB diplexer may include a second resonator layer on a second side of the substrate that is opposite the first side of the substrate. Moreover, the first resonator layer and the second resonator layer may be electrically coupled to each other by metal that extends from the first side of the substrate to the second side of the substrate.

In some embodiments, the metal may include: metal plating on a sidewall of an opening in the substrate; and/or a plurality of metallized vias that extend through the substrate. Moreover, the sidewall of the opening may include a non-plated through-hole that is free of the metal plating.

A multi-pole filter, according to some embodiments, may include a substrate including a first resonator layer on a first side of the substrate and a second resonator layer that is electrically coupled to the first resonator layer and is on a second side of the substrate that is opposite the first side of the substrate. The first resonator layer may include adjacent first and second resonators that are capacitively coupled to each other across a horizontal gap therebetween. The second resonator layer may include adjacent third and fourth resonators that are capacitively coupled to each other across a horizontal gap therebetween. Moreover, the first resonator may overlap the third resonator, and the first and second resonators may both overlap the fourth resonator.

In some embodiments, the first resonator may be wider than the second resonator and wider than the third resonator. An entirety of the second resonator may overlap the fourth resonator, and only a portion of the first resonator may overlap the fourth resonator. Moreover, the portion of the first resonator may have a vertical capacitive coupling to the fourth resonator.

### BRIEF DESCRIPTION OF THE DRAWINGS

FIGS. 1A-1D are views of a filter according to embodiments of the present inventive concepts.

FIGS. 1E and 1F are graphs illustrating filtering responses of the filter of FIGS. 1A-1D.

FIGS. 2A-2H are views of filters according to embodiments of the present inventive concepts.

FIGS. 3A and 3B are views of a filter including resonators with tapered widths according to embodiments of the present inventive concepts.

FIG. 3C is a graph illustrating filtering responses of the filter of FIGS. 3A and 3B.

FIGS. 4A and 4B are views of a filter including digital and interdigital resonators according to embodiments of the present inventive concepts.

FIG. 4C is a graph illustrating filtering responses of the filter of FIGS. 4A and 4B.

FIGS. 5A and 5B are views of a filter including digital and interdigital resonators according to embodiments of the present inventive concepts.

FIG. 5C is a graph illustrating filtering responses of the filter of FIGS. 5A and 5B.

FIG. 5D is a diagram illustrating capacitances in a filter according to embodiments of the present inventive concepts.

FIGS. 6A-6C are views of a diplexer including a metal junction according to embodiments of the present inventive concepts.

FIG. 6D is a graph illustrating filtering responses of the diplexer of FIGS. 6A-6C.

FIG. 6E is a top view of a diplexer including a common resonator according to embodiments of the present inventive concepts.

FIGS. 6F-6H are views of a diplexer including a solder mask according to embodiments of the present inventive concepts.

FIG. 6I is a graph illustrating filtering responses of the diplexer of FIGS. 6F-6H.

FIGS. 6J and 6K are views of PCB sidewalls of filters according to embodiments of the present inventive concepts.

FIGS. 6L and 6M are views of a diplexer including plated sidewalls according to embodiments of the present inventive concepts.

FIGS. 7A-7C are views of a filter according to embodiments of the present inventive concepts.

### DETAILED DESCRIPTION

Pursuant to embodiments of the present inventive concepts, filters, such as diplexers, having double-sided resonator structures are provided. The double-sided resonator structures can advantageously provide a high Q-factor (“high Q”), high power, high performance, improved tolerance control for critical dimensions in fabrication, low cost, low weight, and/or a PCB input/output interface that facilitates easy Monolithic Microwave Integrated Circuit (MMIC) integration. High Q may result from reduced current density on resonators of a double-sided resonator structure relative to resonators of a single-sided resonator structure.

In some embodiments, the high-Q filters are based on PCB-fabrication processes. As an example, a high-Q PCB filter according to embodiments of the present inventive concepts can provide a Q-factor of about 1000 or higher, whereas conventional PCB filters may have a Q-factor of about 100. Moreover, one challenge with conventional PCB-based filters is their PIM performance. For example, though PIM levels of 150 dBm are desirable, some PCB-based filters only achieve levels of about 120 dBm, due to rough metal surfaces on the underside and/or side edges of PCB resonators. The double-sided resonator structures included in filters according to embodiments of the present inventive concepts, however, can reduce current flow on the rough underside of resonators, and thus can reduce PIM issues and increase Q.

Though PCB filters provide one example of filters that can implement a double-sided resonator structure according to embodiments of the present inventive concepts, double-sided resonator structures are not limited to PCB filters. Rather, a double-sided resonator structure according to embodiments of the present inventive concepts can be included on a non-PCB substrate, such as a dielectric substrate. A dielectric substrate, in comparison with a PCB substrate, may advantageously (i) facilitate thicker resonators, (ii) facilitate polishing of metal for increased smoothness, (iii) facilitate use of low-loss dielectric materials that reduce dielectric loss for a filter, and/or (iv) reduce cost.

Example embodiments of the present inventive concepts will be described in greater detail with reference to the attached figures.

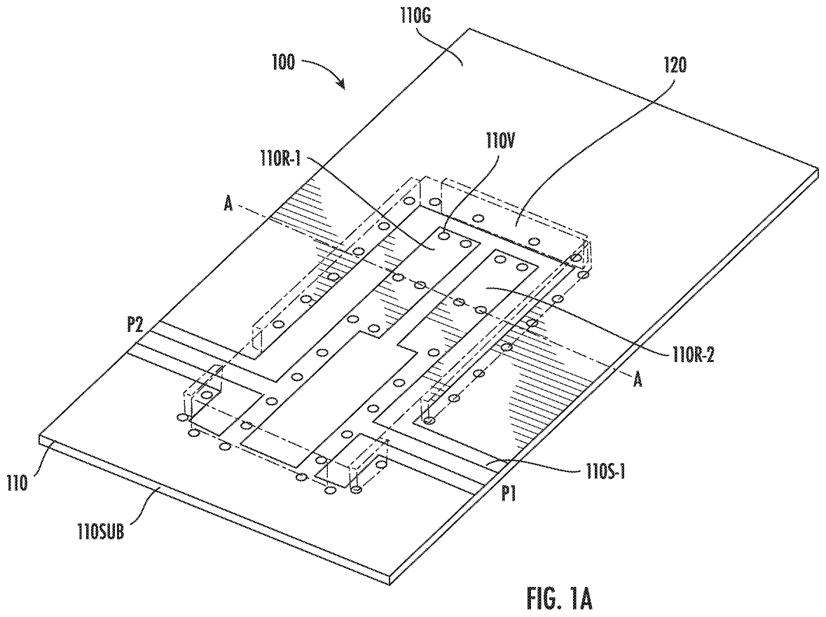

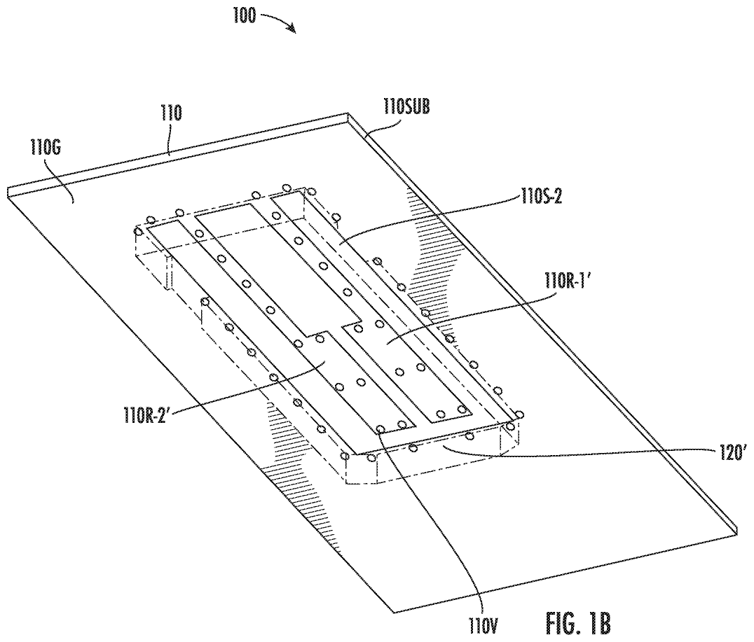

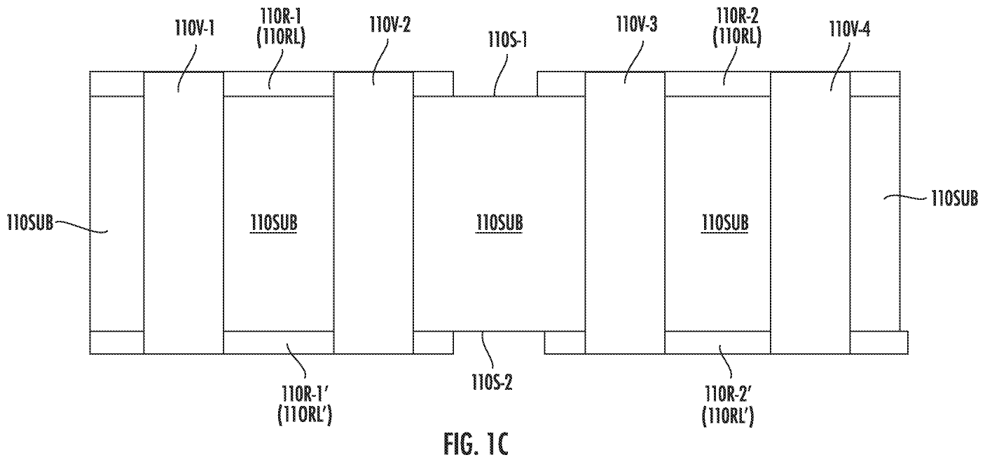

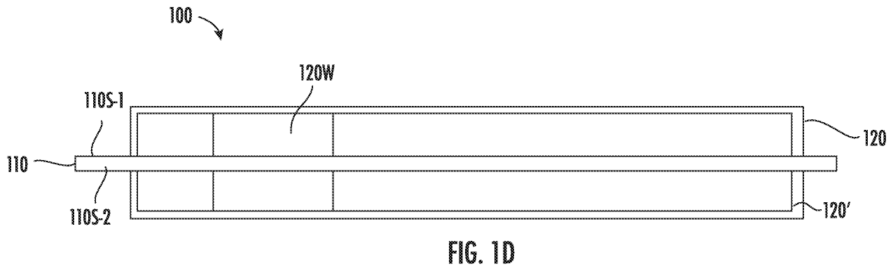

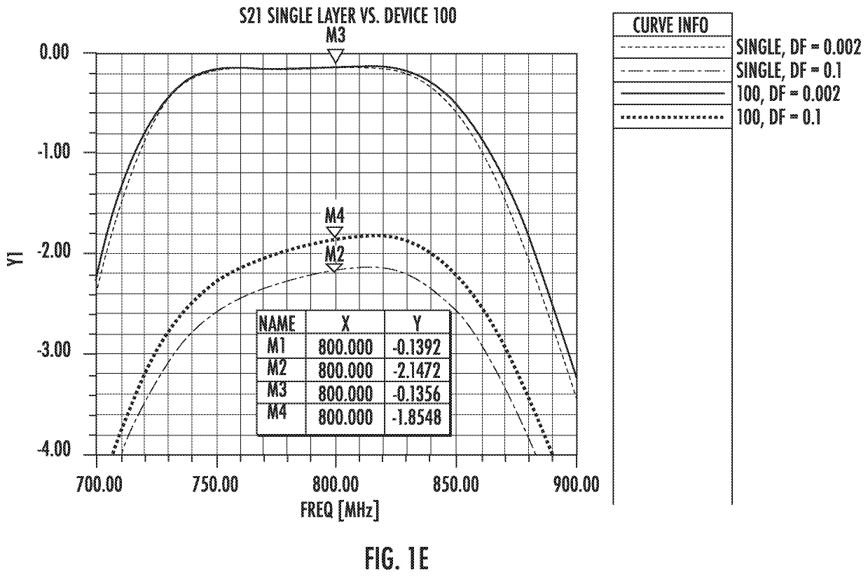

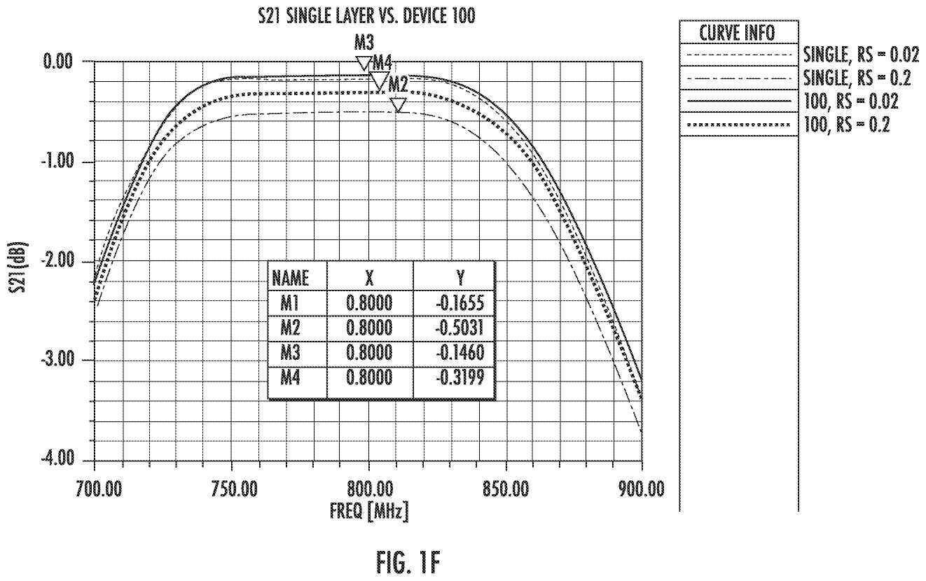

FIGS. 1A-1D are views of a filter 100 according to embodiments of the present inventive concepts. FIG. 1A is a top perspective view of the filter 100. The filter 100 may comprise a PCB 110 that includes a substrate 110SUB and a plurality of resonators 110R. The resonators 110R may include a first resonator 110R-1 and a second resonator 110R-2 that are spaced apart from each other on a first side 110S-1 of the substrate 110SUB. The first resonator 110R-1 and the second resonator 110R-2 may be respective patch resonators, which may be referred to herein as “patches.” Moreover, the PCB 110 may also include a ground portion 110G that is on the first side 110S-1 of the substrate 110SUB.

The filter 100 has a first port P1 and a second port P2 that are connected to the second resonator 110R-2 and the first resonator 110R-1, respectively. In some embodiments, a metal cover 120 may be over the resonators 110R on the first side 110S-1 of the substrate 110SUB. Additionally or alternatively, a plurality of metallized vias 110V may penetrate the substrate 110SUB and connect to the resonators 110R. The metallized vias 110V may be, for example, plated through-hole (PTH) vias.

FIG. 1B is a bottom perspective view of the filter 100. As shown in FIG. 1B, a plurality of resonators 110R′ may be on a second side 110S-2 of the substrate 110SUB that is opposite the first side 110S-1 of the substrate 110SUB. The resonators 110R′ may include a first resonator 110R-1′ and a second resonator 110R-2′ that are spaced apart from each other on the second side 110S-2 of the substrate 110SUB. In some embodiments, a metal cover 120′ may be over the resonators 110R′ on the second side 110S-2 of the substrate 110SUB.

The metal covers 120 and 120′ may advantageously provide electromagnetic interference (EMI) shielding and grounding for the filter 100. For example, the metal covers 120 and 120′ may enhance EMI performance by isolating the resonators 110R and 110R′ from the environment. Moreover, the metal covers 120 and 120′ may inhibit energy from resonating to the environment, may help maintain a resonant frequency in a desired range, and/or may increase the Q-factor of the filter 100.

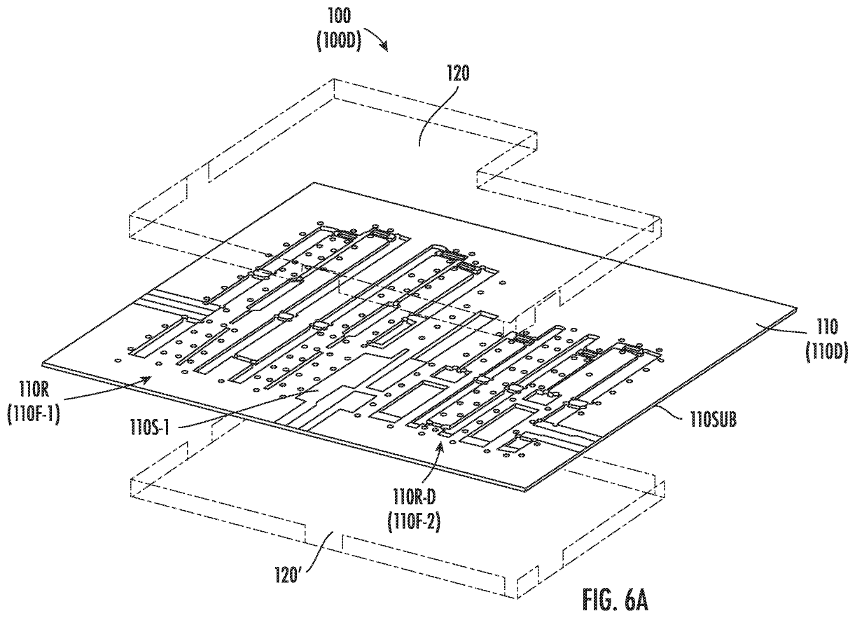

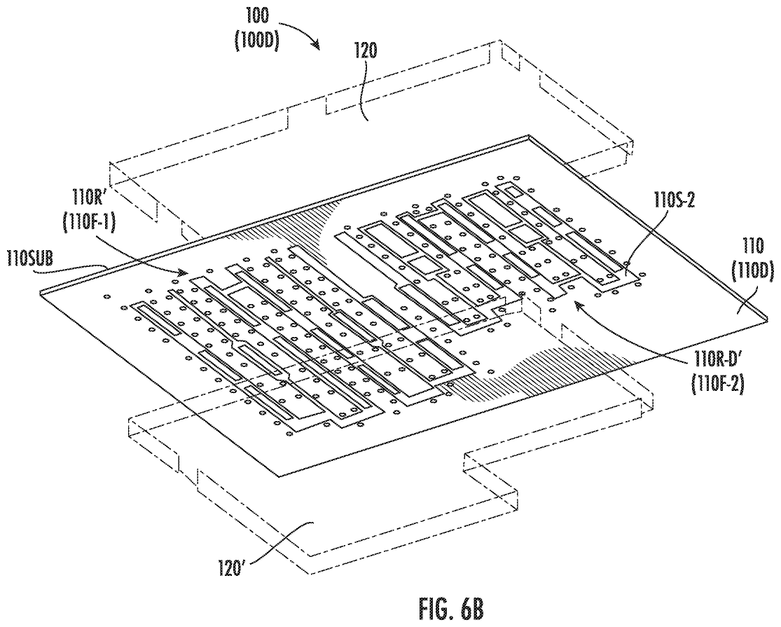

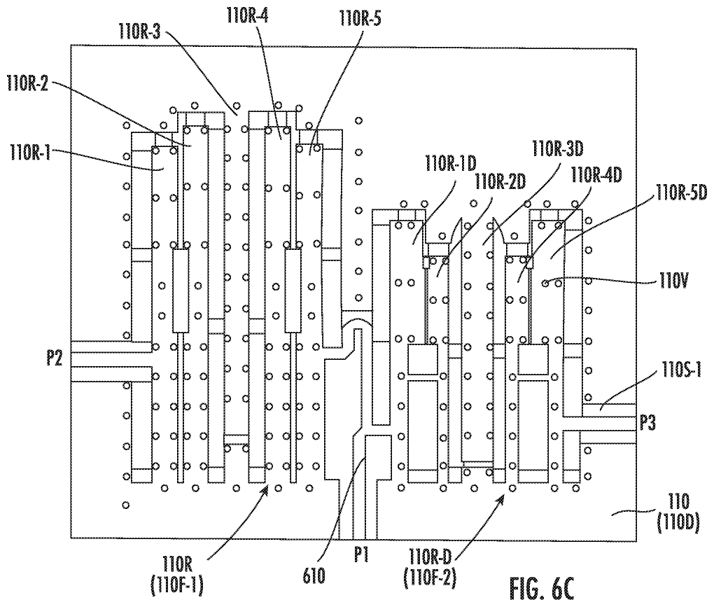

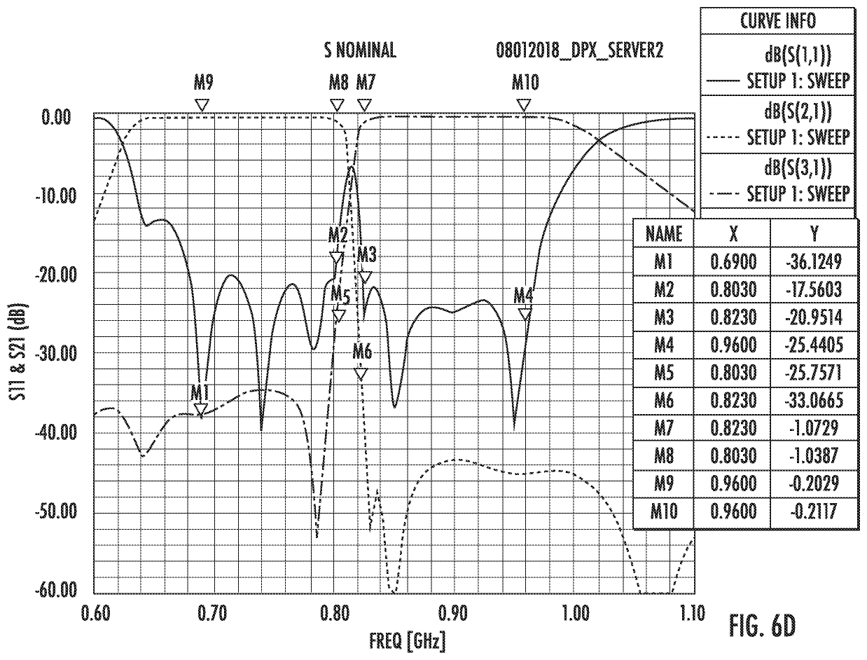

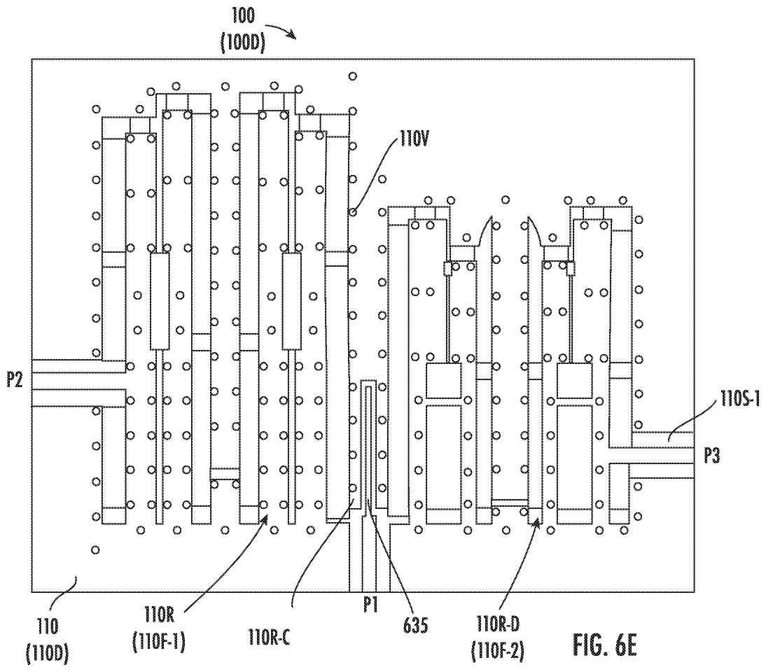

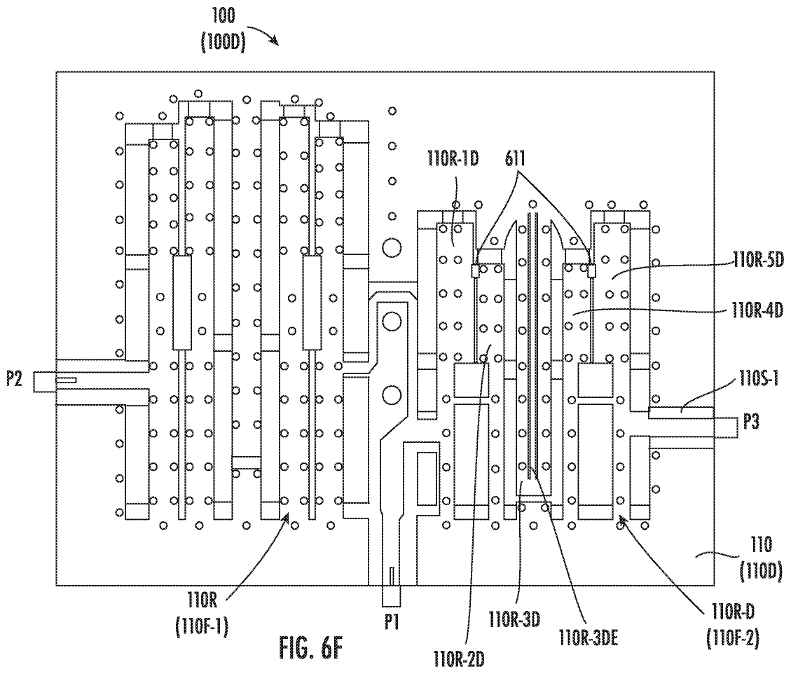

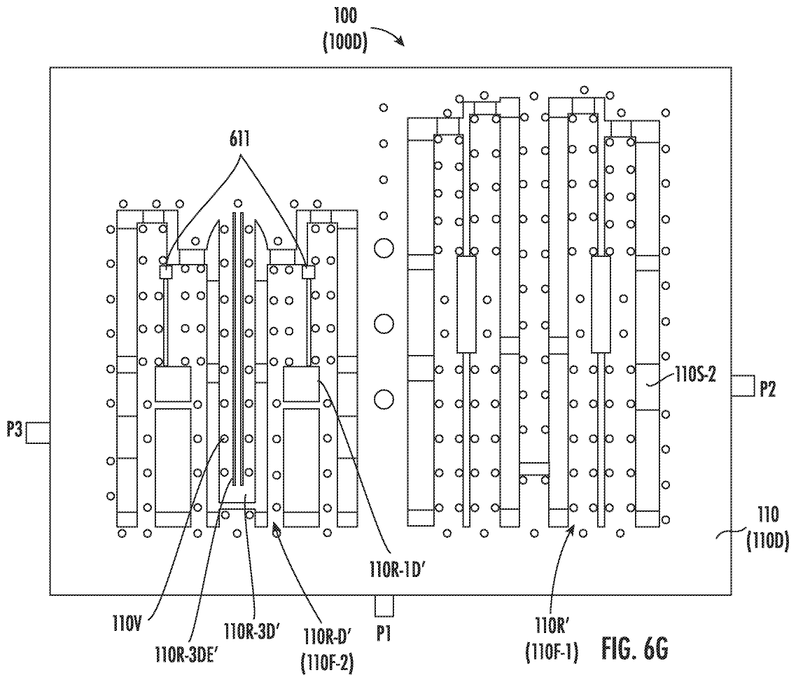

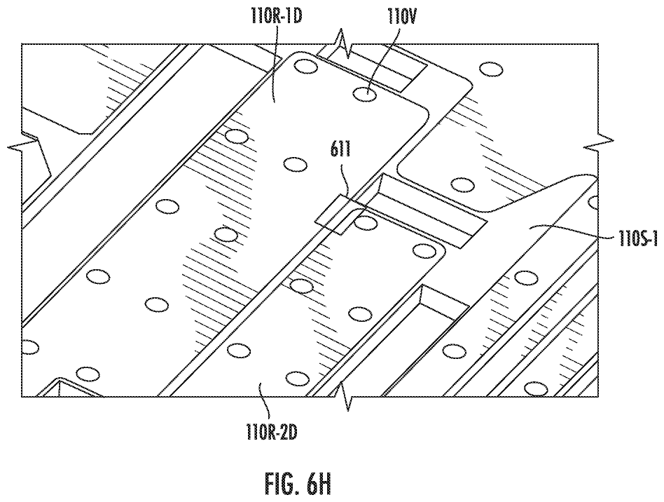

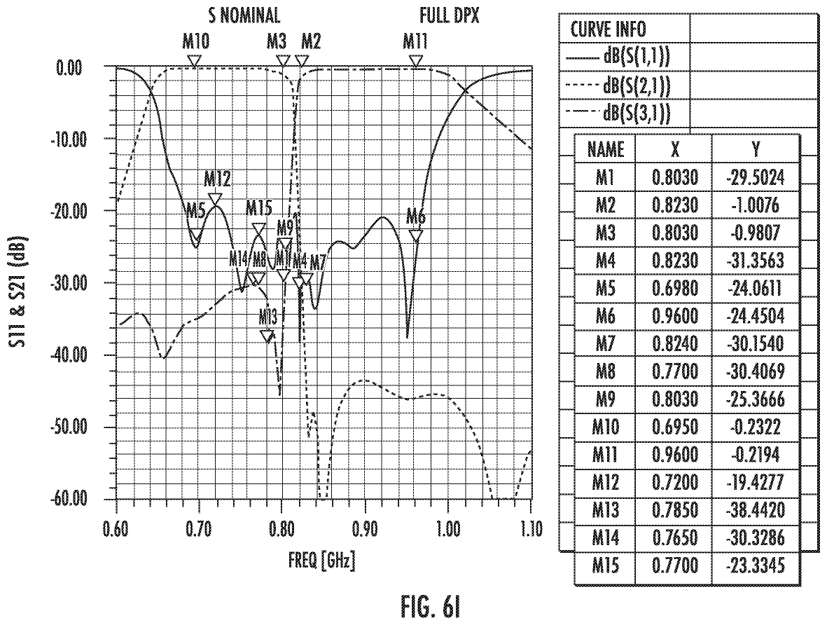

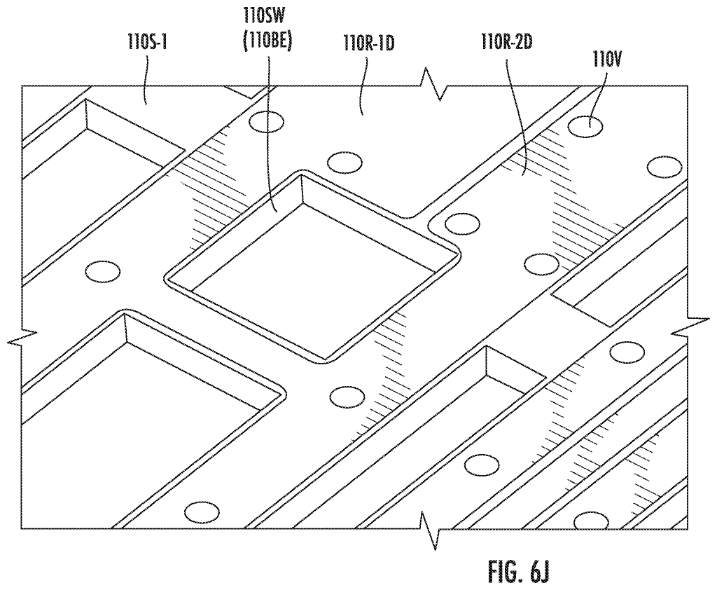

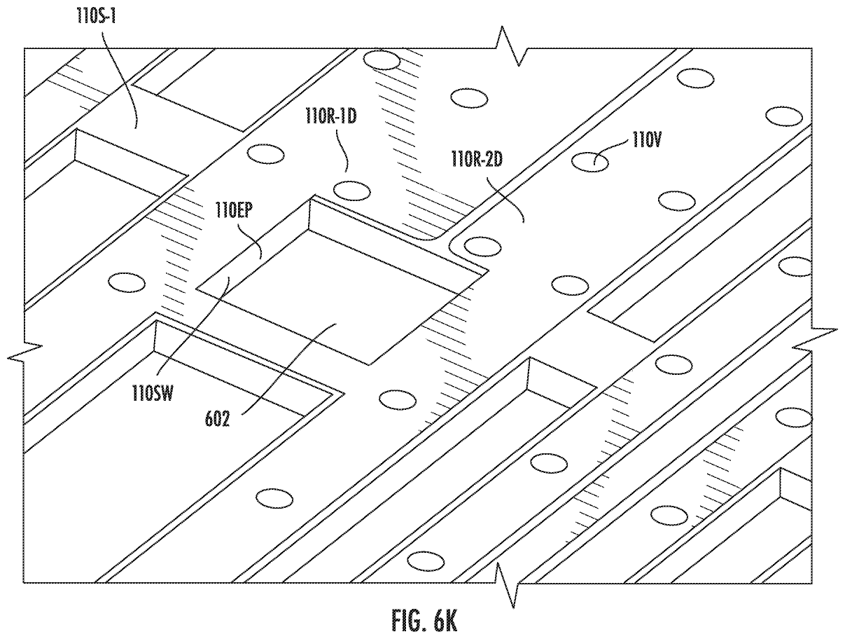

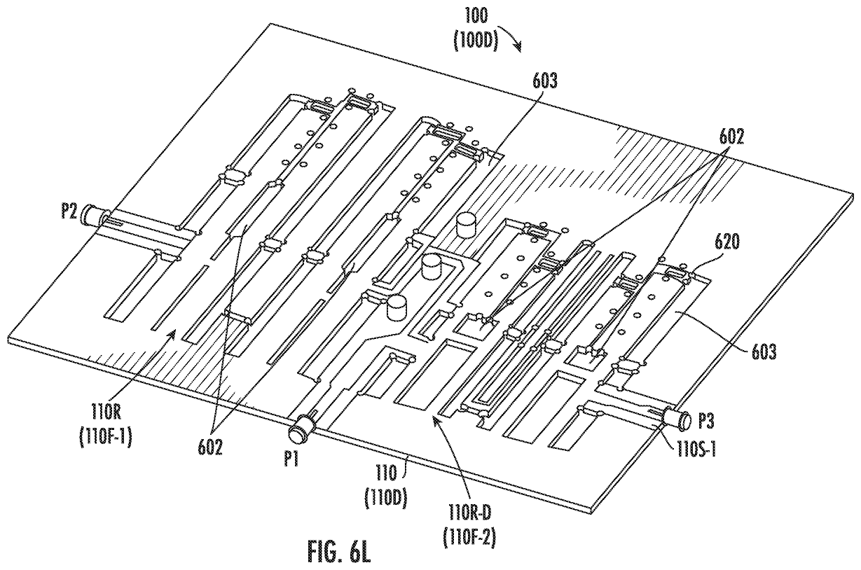

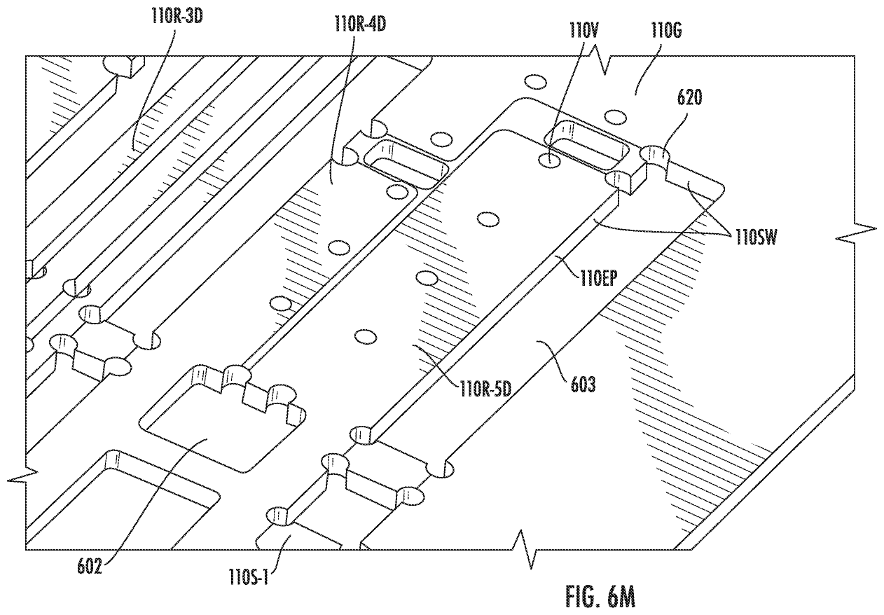

FIG. 1C is a cross-sectional view along a line A-A of FIG. 1A. As shown in FIG. 1C, the resonators 110R on the first side 110S-1 of the substrate 110SUB may be physically and electrically coupled to the resonators 110R′ on the second side 110S-2 of the substrate 110SUB by the metallized vias 110V that penetrate the substrate 110SUB. For example, a first metallized via 110V-1 and/or a second metallized via 110V-2 may extend through the substrate 110SUB to electrically connect the first resonator 110R-1 and the first resonator 110R-1′ to each other. Similarly, a third metallized via 110V-3 and/or a fourth metallized via 110V-4 may extend through the substrate 110SUB to electrically connect the second resonator 110R-2 and the second resonator 110R-2′ to each other. In addition to, or as an alternative to, the metallized vias 110V, the resonators 110R may be physically and electrically coupled to the resonators 110R′ by metal plating 110EP (FIGS. 6K and 6M) that extends from the first side 110S-1 of the substrate 110SUB to the second side 110S-2 of the substrate 110SUB. The metal plating 110EP may be on one or more sidewalls 110SW (FIGS. 6K and 6M) of one or more openings in the substrate 110SUB.

The term “vertical connection,” as used herein, may describe metal plating 110EP or a metallized via 110V. For example, a vertical connection that extends vertically from the first side 110S-1 to the second side 110S-2 to electrically connect the first resonator 110R-1 to the first resonator 110R-1′ may comprise (i) metal plating 110EP, (ii) the metallized via 110V-1, or (iii) the metallized via 110V-2. In some embodiments, a plurality of vertical connections, such as both of the metallized vias 110V-1, 110V-2 or a combination of metal plating 110EP and the metallized via(s) 110V-1/110V-2, may electrically connect the first resonator 110R-1 to the first resonator 110R-1′. Moreover, the term “by metal” may be used herein to describe a connection by metal plating 110EP and/or metallized via(s) 110V.

Though the resonators 110R and the resonators 110R′ may be referred to herein as a “first plurality of resonators” and a “second plurality of resonators,” respectively, the resonators 110R and the resonators 110R′ may collectively operate as one group of resonators, due to being physically and electrically coupled to each other by the metallized vias 110V and/or metal plating 110EP (FIGS. 6K and 6M). For example, the first resonator 110R-1 and the first resonator 110R-1′ may function together as a single first resonator, due to the vertical connection between the first resonator 110R-1 and the first resonator 110R-1′. Similarly, the second resonator 110R-2 and the second resonator 110R-2′ may function together as a single second resonator. As a result, the filter 100 may be a two-pole filter, where the combination of the first resonator 110R-1 and the first resonator 110R-1′ accounts for one of the two transmission poles.

In some embodiments, the substrate 110SUB is a PCB substrate of the PCB 110, the resonators 110R are etched on the first side 110S-1 of the substrate 110SUB, and the resonators 110R′ are etched on the second side 110S-2 of the substrate 110SUB. The resonators 110R and 110R′ can thus provide a double-sided resonator structure in the filter 100. Accordingly, the PCB 110 may be a double-sided PCB filter, such as a double-sided PCB diplexer, where a diplexer is a device having two filters with different respective frequency bands. A double-sided PCB filter may include, for example, a first resonator layer 110RL comprising the resonators 110R, and a second resonator layer 110RL′ that is on an opposite side of the PCB 110 from the first resonator layer 110RL and that comprises the resonators 110R′. The first and second resonator layers 110RL and 110RL′ may be physically and electrically coupled to each other, such as by metal plating 110EP (FIGS. 6K and 6M) and/or one or more metallized vias 110V. In some embodiments, the first and second resonator layers 110RL and 110RL′ may comprise first and second metal layers, such as first and second copper (Cu) layers.

As an alternative to providing the first and second resonator layers 110RL and 110RL′ as PCB resonators on the PCB 110, the first and second resonator layers 110RL and 110RL′ may be stamped metal on the substrate 110SUB, which may be a non-PCB substrate. For example, the non-PCB substrate may be a plastic (or other dielectric) substrate. The use of the PCB 110, on the other hand, may be advantageous, in that etching the first and second resonator layers 110RL and 110RL′ on the PCB 110 is a relatively stable process. A tradeoff of the etching, however, may exist between the roughness and the adhesiveness of the material (e.g., Cu) of the first and second resonator layers 110RL and 110RL′ toward the PCB 110.

FIG. 1D is a side view of the filter 100. This side view illustrates the metal cover 120 that is on the first side 110S-1 of the substrate 110SUB, as well as the metal cover 120′ that is on the second side 110S-2 of the substrate 110SUB. For example, the metal cover 120 and the metal cover 120′ may be top and bottom metal covers, respectively, each of which may include a sidewall opening/window 120W. Each sidewall opening/window 120W may allow a metal line to pass through the opening/window 120W to connect one of the ports P1, P2 (FIG. 1A) to one of the resonators 110R/110R′. Multiple sidewall openings/windows 120W may be provided (e.g., one for each port P1, P2).

FIGS. 1E and 1F are graphs illustrating filtering responses (insertion losses S21) for the filter 100 of FIGS. 1A-1D. By providing the resonators 110R and the resonators 110R′ on opposite sides 110S-1 and 110S-2 of the substrate 110SUB, the filter 100 may be a low-loss filter.

Insertion loss refers to the loss associated with adding an element along a transmission line. When an RF signal is excited at the first port P1 (FIG. 1A), the insertion loss for the filter 100 is referred to as S21. The insertion loss may include both ohmic loss and dielectric (substrate) loss. The ohmic loss has two mechanisms. The first mechanism is metallic losses based on the conductivity of the metal along the signal path. For example, Cu has a conductivity of 5.8×10⁸ siemens/meter and aluminum (Al) has a conductivity of 3.3×10⁸ siemens/meter. The lower the conductivity, the higher the metallic losses. The second mechanism of ohmic loss is surface roughness losses. The interface between a Cu layer and a substrate is typically rougher than the outer surface of the Cu layer that faces away from the substrate, due to the adhesive process of the two materials of a PCB. The roughness of the Cu layer surface facing toward the substrate can significantly increase ohmic loss.

As shown in FIGS. 1A-1C, each of the resonator layers 110RL and 110RL′ may comprise two patches. In particular, the resonator layer 110RL may have patches 110R-1 and 110R-2 on the first side 110S-1 of the substrate 110SUB, and the resonator layer 110RL′ may have patches 110R-1′ and 110R-2′ on the second side 110S-2 of the substrate 110SUB. The patches of the two resonator layers 110RL and 110RL′ may be electrically coupled to each other by PTH metallized vias 110V.

By including both of the resonator layers 110RL and 110RL′ together as a double-resonator structure, the filter 100 shown in FIGS. 1A-IC may have advantages over a filter that has only a single resonator layer on a substrate. These advantages may include smaller ohmic loss and smaller dielectric loss. First, the use of the metallized vias 110V to electrically connect the two resonator layers 110RL and 110RL′ to each other may reduce/eliminate voltage drop and electric field through the substrate 110SUB, thus reducing/minimizing dielectric loss. For example, the voltage drop between the resonator layer 110RL and the resonator layer 110RL′ may be zero (or almost zero). Second, due to having substantially zero electric field within the substrate 110SUB, the flow of current along the interface between the resonator layer 110RL (or the resonator layer 110RL′) and the substrate 110SUB may be reduced/minimized, thus reducing ohmic loss caused by surface roughness at the interface. Third, the increased resonator thickness that results from using the two resonator layers 110RL and 110RL′, rather than only a single resonator layer, reduces current density flowing along the resonator layers 110RL and 110RL′, which further reduces ohmic loss. In addition to the benefit(s) of reduced loss, the increased resonator thickness can increase power handling.

The graphs of FIGS. 1E and 1F compare performance of the filter 100 that has a double-resonator structure with a conventional filter that has only a single resonator layer. FIG. 1E compares (a) insertion losses S21 for the filter 100 with (b) insertion losses S21 for a conventional filter that has only a single resonator layer, at different levels of substrate loss DF. DF is unitless, is short for dissipation loss factor, and represents an electrical property of the substrate material. FIG. 1F compares (a) insertion losses S21 for the filter 100 with (b) insertion losses S21 for a conventional filter that has only a single resonator layer, at different levels of Rs (units: ohms/square), which denotes surface roughness loss as surface resistance.

As shown in FIG. 1E, a filter with only a single resonator layer has insertion losses S21 (at 800 MHz)=0.1392 dB and 2.1472 dB when DF=0.002 and DF=0.1, respectively, whereas the filter 100 with a double-resonator structure has insertion losses S21 (at 800 MHz)=0.1356 dB and 1.8548 dB when DF=0.002 and 0.1, respectively. The filter 100 thus has smaller dielectric loss than the filter that only uses a single resonator layer. Though the improvement in insertion loss performance is relatively small when DF=0.002, such as for substrates that have very low dielectric losses, a significant reduction of over 0.25 dB in insertion loss is provided by the filter 100 when DF=0.1. Materials with smaller DF tend to be more expensive. Moreover, in a humid environment, water absorption will increase the DF of many materials.

Also, as shown in FIG. 1F, a filter with only a single resonator layer has insertion losses S21 (at 800 MHz)=0.1655 dB and 0.5031 dB when Rs=0.02 and Rs=0.2, respectively, whereas the filter 100 has insertion losses S21 (at 800 MHz)=0.1460 dB and 0.3199 dB when Rs=0.02 and 0.2, respectively. The filter 100 thus has smaller ohmic loss than the filter that only uses a single resonator layer. In particular, for metal foil with typical surface resistance levels, such as Rs=0.2, the filter 100 provides about a 0.2 dB reduction in insertion loss. Surface roughness of the metal layer leads to an increase of loss. Surface resistance (Rs) is used to herein to estimate the loss effect caused by surface roughness. The unit of surface resistance here is ohms/square. Rs=0.02 ohms/square may be a good estimation for RO3003™ rolled copper with the roughness parameter=0.4 Sq (micron), which is a very smooth copper material. RO3003™ ED (electrodeposited) copper may have roughness parameters ranging from 0.5˜3.5 Sq (micron). Rs=0.2 ohms/square matches some of the poor results based on ED copper PCBs. RO3003™ rolled Cu materials, however, can be significantly more expensive than RO3003™ ED Cu materials.

Though PCBs with very low dielectric losses and/or very low surface resistance levels can be used in some embodiments, such PCBs can be unduly expensive relative to PCBs with typical dielectric losses and/or typical surface resistance levels. Less-expensive PCB-based filters may provide a cost advantage both over more-expensive PCB-based filters and over fully-mechanical filters.

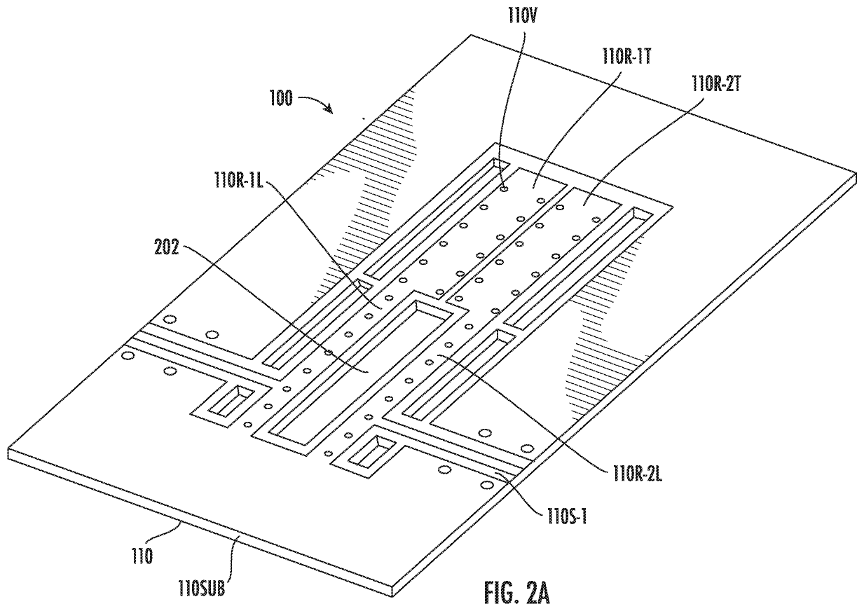

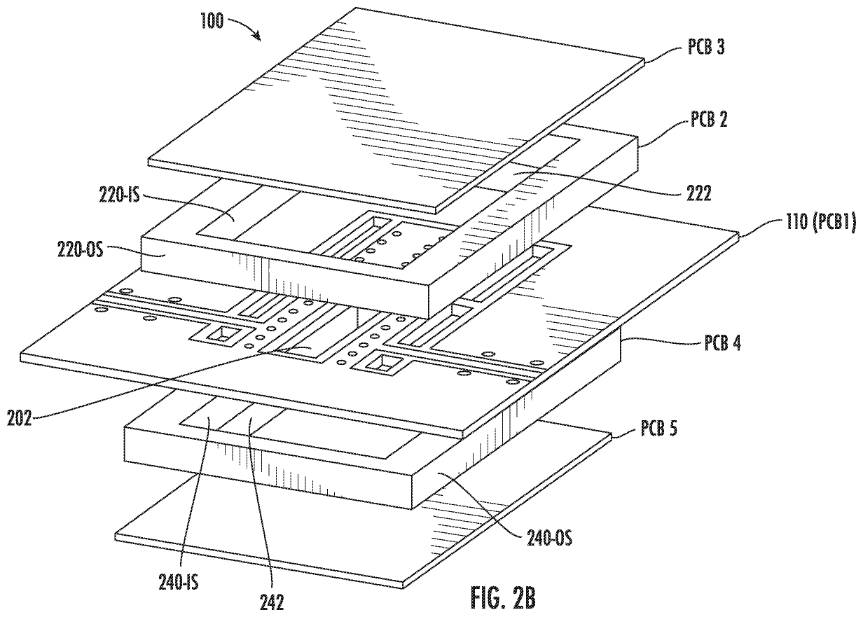

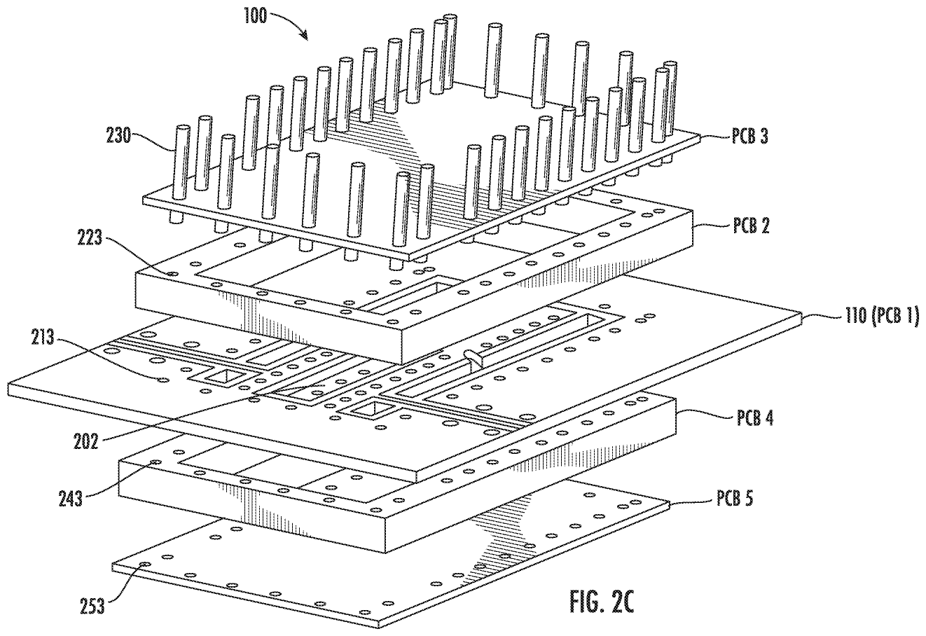

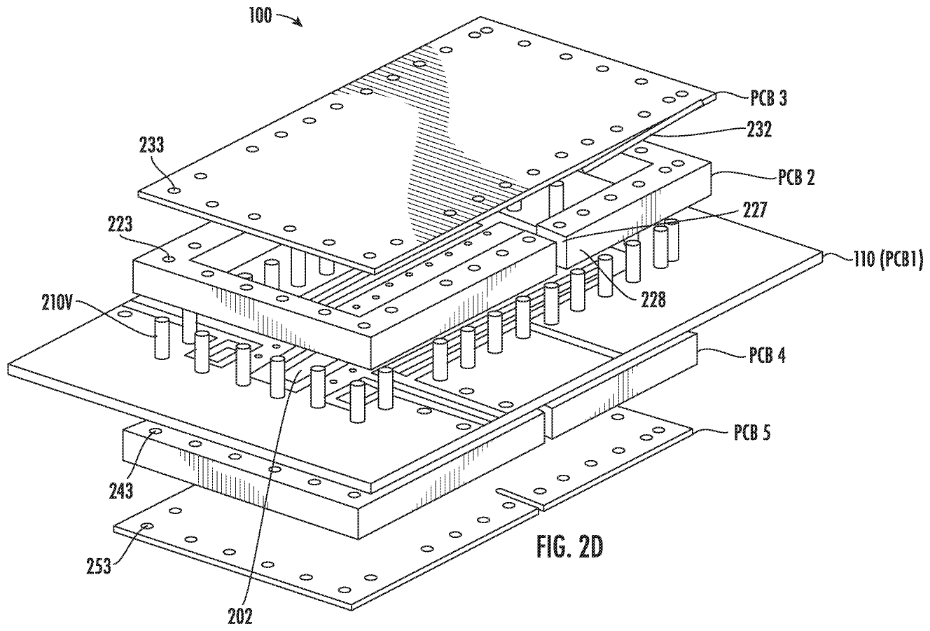

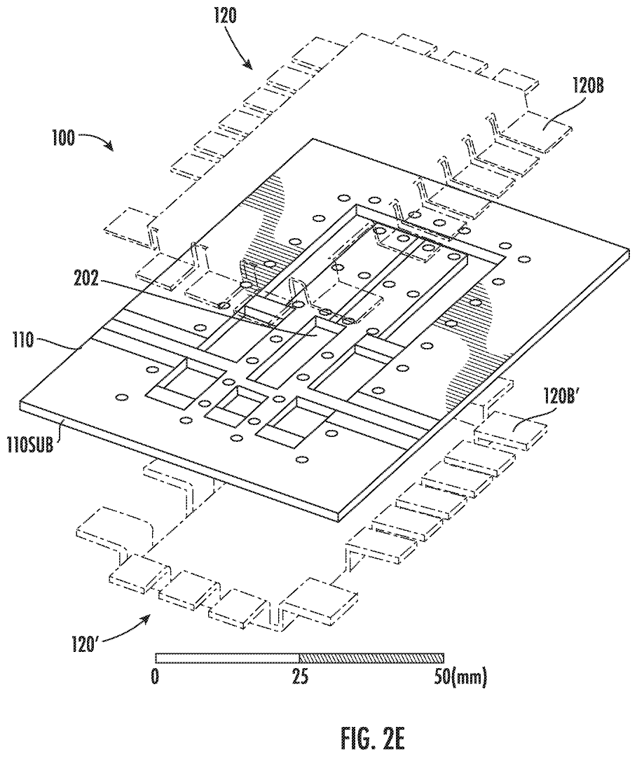

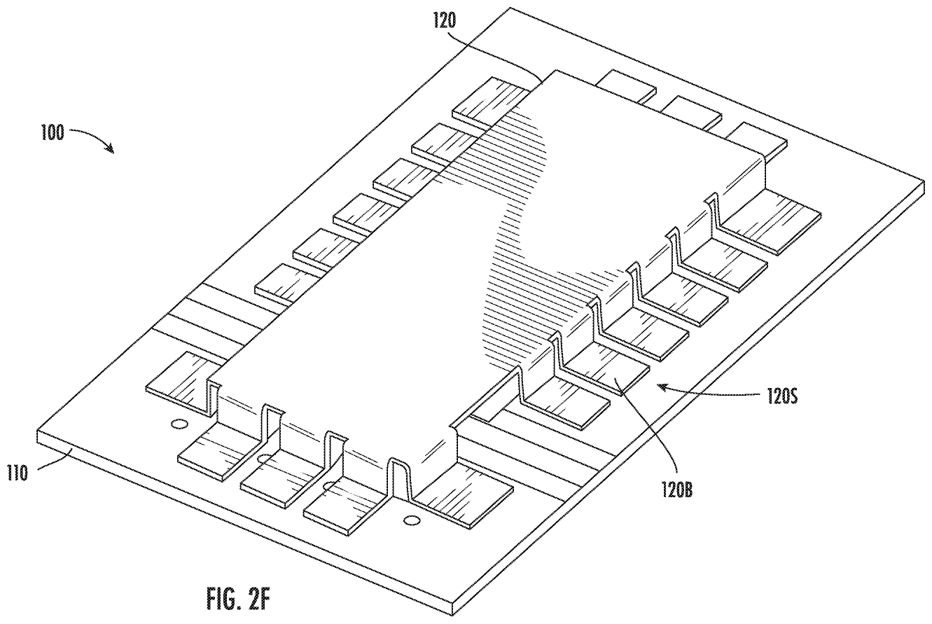

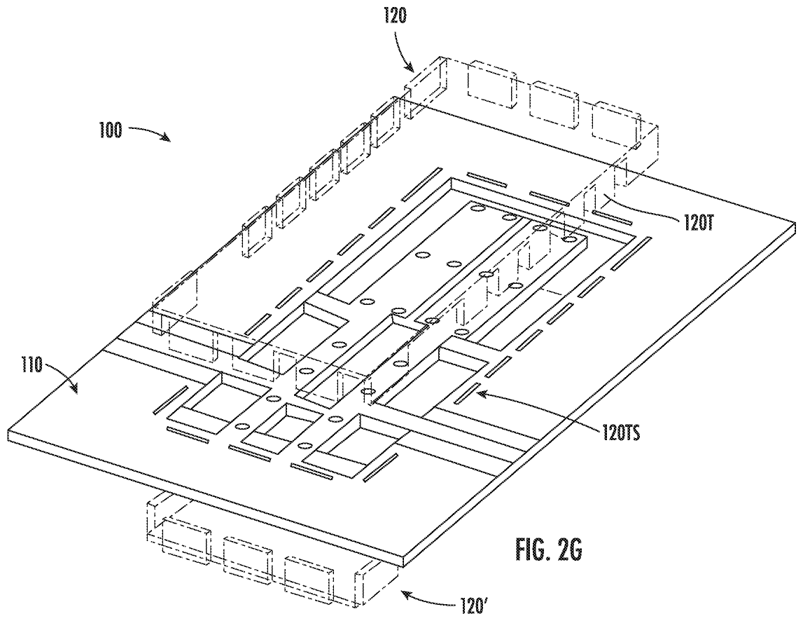

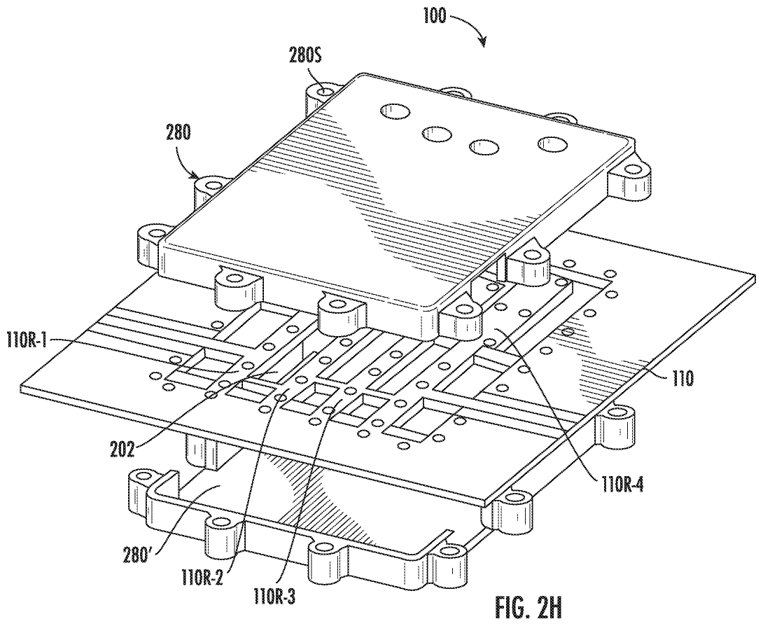

FIGS. 2A-2H are views of filters 100 according to embodiments of the present inventive concepts. As shown in the top perspective view provided by FIG. 2A, a filter 100 may, in some embodiments, include an opening 202 that extends through the substrate 110SUB. The opening 202 may further reduce insertion and/or dielectric loss in the filter 100 relative to the example of FIG. 1A in which the opening 202 is omitted.

In some embodiments, the opening 202 may extend through a region of the substrate 110SUB that is between first and second ones 110R-1, 110R-2 of the resonators 110R and between first and second ones 110R-1′, 110R-2′ (FIGS. 1B and 1C) of the resonators 110R′. For example, the opening 202 may be between respective first portions 110R-1L, 110R-2L of the first and second ones 110R-1, 110R-2 of the resonators 110R, and between respective first portions 110R-1L, 110R-2L of the first and second ones 110R-1′, 110R-2′ of the resonators 110R′. The first portions 110R-1L, 110R-2L may be narrower than respective second (e.g., upper) portions 110R-1T, 110R-2T of the first and second ones 110R-1′, 110R-2′ of the resonators 110R′.

Referring to the exploded top perspective view provided by FIG. 2B, the filter 100 of FIG. 2A may be in a stack of PCBs that provides EMI shielding and grounding for the filter 100. For example, the stack of PCBs may include PCB2-PCB5, which may be an alternative to the metal covers 120 and 120′ (FIG. 1D).

A PCB 110 that includes the opening 202 may also be identified herein as a PCB1 that is in the middle of the stack of PCBs. The PCB2 and the PCB3 may be on the first side 110S-1 of the substrate 110SUB of the PCB1, and the PCB4 and the PCB5 may be on the second side 110S-2 of the substrate 110SUB of the PCB1. In some embodiments, the PCB2 and the PCB4 may each be soldered to the PCB1. Similarly, the PCB3 and the PCB5 may be soldered to the PCB2 and the PCB4, respectively.

The PCB2 and the PCB4 may be used as framework (or spacer) PCBs in the filter 100 by partial excavation of the PCB2 and the PCB4. For example, the PCB2 may be between the PCB1 and the PCB3 and include an opening 222. Also, the PCB4 may be between the PCB1 and the PCB5 and may include an opening 242. In some embodiments, the PCB2 may comprise metallized inner sidewalls 220-IS inside the opening 222 and/or may comprise metallized outer sidewalls 220-OS on an outer perimeter of the PCB2. The PCB4 may comprise metallized inner sidewalls 240-IS inside the opening 242 and/or may comprise metallized outer sidewalls 240-OS on an outer perimeter of the PCB4. Moreover, in some embodiments, plated vias can be used in the PCB2 and/or the PCB4 instead of metallized sidewalls.

As an alternative to soldering the PCB1-PCB5 to each other, the PCB1-PCB5 may be bonded to each other by one or more screws 230 (e.g., metal screws or plastic screws), as shown in the exploded top perspective view of FIG. 2C. The term “screw” is used herein to broadly include any type of threaded fastener, including a bolt. The PCB2 may include one or more openings 223 that receive the screw(s) 230. Similarly, the PCB1, PCB4, and PCB5 may include openings 213, 243, 253 that receive the screw(s) 230. As an example, the filter 100 of FIG. 2A may be in a PCB stack and may include a screw 230 that extends from an opening 233 (FIG. 2D) in the PCB3 to one of the openings 223 of PCB2, to connect the PCB2 and the PCB3 to each other. The screw(s) 230 may obviate the need for metallized sidewalls and/or plated vias (e.g., PTH vias 210V in FIG. 2D) in the PCB2 and the PCB4.

As discussed herein, solder and/or screw(s) 230 may be used to connect the PCB2-PCB5 to the PCB1. The PIM performance of the screw(s) 230 may be about the same as the PIM performance of solder. Solder, however, can be more difficult than the screw(s) 230 to implement in the filter 100. In some embodiments, as an alternative to using the screw(s) 230 or soldering the PCB1-PCB5 to each other, the PCB1-PCB5 can be glued together.

The structure in FIG. 2C, like the structure in FIG. 2B, provides an alternative to the metal covers 120 and 120′ for EMI shielding and grounding for the filter 100. Accordingly, top and/or bottom surfaces of the PCB3 and the PCB5 can be metallized or metal plates can be used in lieu of the PCB3 and the PCB5, which are the top and bottom PCBs, respectively, in the stack. It may be desirable for the PCB2-PCB5 to be at ground potential. Additionally or alternatively, dielectric substrates may be used in lieu of the PCB2 and the PCB4. The dielectric substrates may be electrically beneficial in embodiments in which the screw(s) 230 connected thereto comprise metal.

Referring to the exploded top perspective view of FIG. 2D, PCB1-PCB5 may be bonded to each other by pre-pregs and electrically coupled to each other by PTH vias. For example, the filter 100 of FIG. 2A may be in a PCB stack and may include a pre-preg 232 that connects PCB2 and PCB3 to each other, and a PTH via 210V that connects PCB1 and PCB2 to each other. Moreover, one or more of PCB1-PCB5 may include at least one canal that connects outer edges thereof to larger openings (e.g., the openings 222 and 242 of FIG. 2B) therein. As an example, the PCB2 may include an opening 227 that extends from the opening 222 (FIG. 2B) to an outer edge 228 of PCB2. This structure in FIG. 2D, like the structures in FIGS. 2B and 2C, provides an alternative to the metal covers 120 and 120′ for EMI shielding and grounding for the filter 100.

In some embodiments, the structure in FIG. 2D may be manufactured by filling hollow portions of PCB1-PCB5 with filling materials, laminating the PCB1-PCB5 with pre-pregs (e.g., the pre-preg 232), and drilling the openings 213 (FIG. 2C), 223, 233, 243, and 253 through the PCB1-PCB5 to facilitate PTH vias 210V. The filling materials can then be gasified (or liquefied) and discharged from a lamination block through the canals to form air cavities (e.g., the openings 222 and 242 of FIG. 2B) inside the PCB stack.

FIG. 2E shows an exploded top perspective view of a filter 100 that includes an opening 202 in a substrate 110SUB that has a metal cover 120 and/or a metal cover 120′ thereon. In particular, the metal cover 120 and/or the metal cover 120′ may be on the substrate 110SUB over the opening 202. In some embodiments, the metal cover 120 and/or the metal cover 120′ may include one or more L-shaped bent metal portions 120B/120B′ that attach to the PCB 110. For example, the metal cover 120 and/or the metal cover 120′ may comprise a metal sheet having a perimeter that is bent to provide the L-shaped bent metal portion(s) 120B/120B′. This structure in FIG. 2E provides one example of an approach to realize EMI shielding and grounding for the filter 100.

FIG. 2F illustrates atop perspective view of a filter 100 that includes the metal cover 120 of FIG. 2E on the PCB 110. Each L-shaped bent metal portion(s) 120B of the metal cover 120 may be attached to the PCB 110 by a solder connection 120S. Additionally or alternatively, the L-shaped bent metal portion(s) 120B of the metal cover 120 may be attached to the PCB 110 by one or more screws, such as metal screws or plastic screws.

FIG. 2G illustrates an exploded top perspective view of a filter 100 in which a metal cover 120 includes one or more tabs 120T that attach to respective slots 120TS in the PCB 110. The tab(s) 120T may be bent 90 degrees toward the PCB 110. A metal cover 120′ may also include one or more tabs 120T that attach to respective slots 120TS in the PCB 110. Accordingly, the metal cover 120 and/or the metal cover 120′ may be installed by inserting the tab(s) 120T into the slot(s) 120TS (e.g., metallized slot(s)). This structure in FIG. 2G provides one example of an approach to realize EMI shielding and grounding for the filter 100. Moreover, to protect against PIM issues, the tab(s) 120T (or other interface(s) with the PCB 110) may be soldered to the PCB 110.

FIG. 2H illustrates an exploded top perspective view of a filter 100 that comprises a machined or die-cast cover 280 over an opening 202 of a PCB 110. The cover 280 may include one or more openings 280S through which screws may attach the cover 280 to the PCB 110. In some embodiments, the PCB 110 may be in a stack between the cover 280 and a similar machined or die-cast cover 280′. This structure in FIG. 2H provides one example of an approach to realize EMI shielding and grounding for the filter 100.

As shown in FIG. 2H, the PCB 110 may comprise four resonators 110R-1, 110R-2, 110R-3, and 110R-4. One or more openings 202 may extend through the PCB 110 between adjacent ones of the resonators 110R-1, 110R-2, 110R-3, and 110R-4. As used herein, the term “adjacent ones” (or “adjacent resonators”) refers to a laterally-adjacent pair of resonators 110R/110R′ that does not have another resonator 110R/110R′ therebetween. The term “non-adjacent ones” (or “non-adjacent resonators”), by contrast, refers to a laterally-adjacent pair of resonators 110R/110R′ that has another resonator 110R/110R′ therebetween.

Due to the four resonators 110R-1, 110R-2, 110R-3, and 110R-4, the filter 100 may comprise a four-pole PCB filter. Any filter 100 according to embodiments of the present inventive concepts may comprise two or more resonators 110R that correspond to respective transmission poles, and thus may be referred to herein as a “multi-pole” filter. Moreover, any filter 100 according to embodiments of the present inventive concepts may comprise a double-sided PCB 110 that includes first and second resonator layers 110RL and 110RL′ (FIGS. 1A-1C).

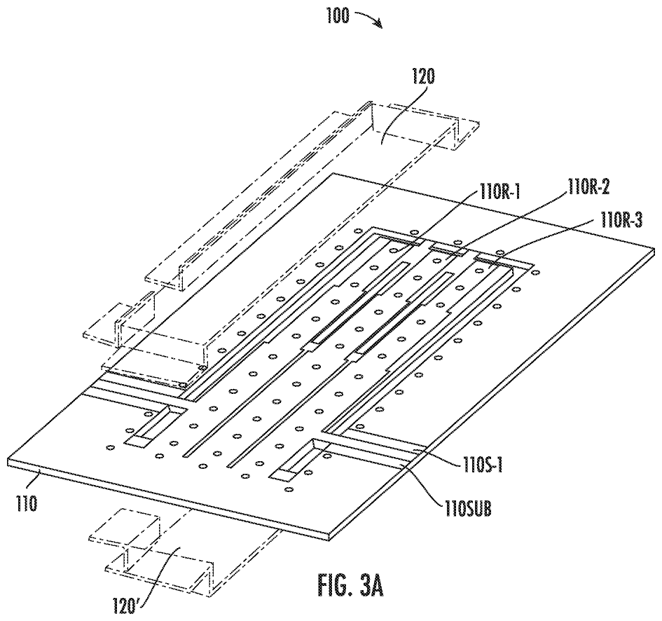

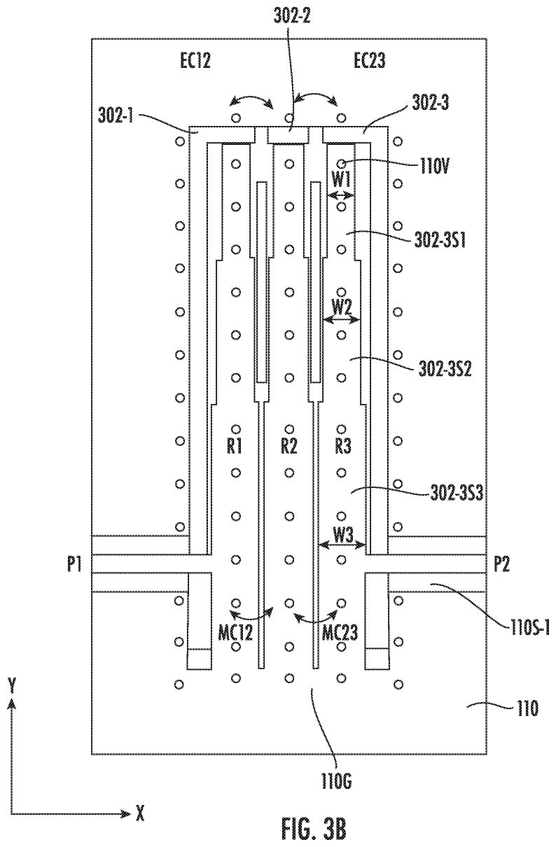

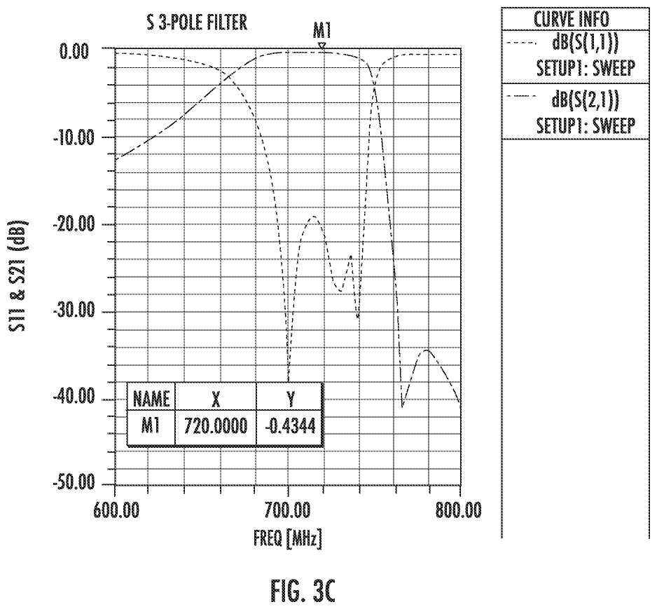

FIGS. 3A and 3B are views of a filter 100 including resonators 110R with tapered widths according to embodiments of the present inventive concepts. As shown in FIG. 3A, the resonators 110R may include three resonators 110R-1, 110R-2, and 110R-3 that are on a PCB 110 of the filter 100. FIG. 3B illustrates an enlarged top view of the PCB 110 of FIG. 3A.

As shown in FIG. 3B, the resonators 110R-1, 110R-2, and 110R-3 may be tapered toward respective openings 302-1, 302-2, and 302-3 in a substrate 110SUB of the PCB 110. For example, one or more of the resonators 110R-1, 110R-2, and 110R-3 may comprise three different widths W1, W2, and W3. As an example, the widest width W3 of the resonator 110R-3 may be farthest from the opening 302-3, whereas the narrowest width W1 may be closest to the opening 302-3. Also, the intermediate width W2 may be between (in terms of both position in the Y direction and measurement in the X direction) the widths W1 and W3. For simplicity of illustration, the resonators 110R-1, 110R-2, and 110R-3 may be denoted herein as “R1,” “R2,” and “R3,” respectively. The resonators R1-R3, which provide a three-pole digital filter of three-section resonators, may be electrically coupled to a resonator layer 110RL′ (FIGS. 1B and 1C) on the opposite, second side 110-S2 of the substrate 110SUB by metallized vias 110V. As used herein, the term “digital” refers to two or more resonators 110R (or 110R′) that are electrically shorted to ground 110G on the same side (among 110S-1 or 110S-2) and the same end of the PCB 110.

The structure in FIG. 3B can provide improved coupling for the filter 100. For example, inductive (magnetic) coupling, as indicated by MC12 and MC23, may be very weak near the open ends (i.e., openings 302-1, 302-2, and 302-3) of the resonators R1-R3 and very strong near the opposite, shorting ends of the resonators R1-R3. The shorting ends are electrically shorted to ground 110G. Also, capacitive coupling, as indicated by EC12 and EC23, may be very strong at the open ends of R1-R3 and very weak at the shorting ends of the resonators R1-R3. The strength of MC12, MC23, EC12, and EC23 can be adjusted by shaping each of the resonators R1-R3 into a plurality of step sections, such as sections 302-3S1, 302-352, and 302-353 having the different widths W1, W2, and W3, respectively. For example, the open ends of the resonators R1-R3 are slim and relatively isolated from each other, so that EC12 and EC23 are relatively weak. The shorting ends of resonators R1-R3, on the other hand, are wider and closer together, so that MC12 and MC23 increase. Accordingly, the structure in FIG. 3B can provide improved coupling for the filter 100, which may comprise a step digital filter in which each of the resonators R1-R3 has a shorting end on the same end of the PCB 110.

The present inventive concepts are not limited to the three sections 302-3S1, 302-3S2, and 302-3S3. Rather, one or more of the resonators R1-R3 may have four, five, or more sections of different widths. As the number of sections increases, the resonator shape can become triangular, trapezoidal, or other tapered shapes. A step digital filter as shown in FIG. 3B is also not limited to PCB structures, but rather can also be used with a non-PCB substrate 110SUB.

FIG. 3C is a graph illustrating filtering responses of the filter 100 of FIGS. 3A and 3B. FIG. 3C demonstrates that when inductive (magnetic) coupling (MC) is greater than electric/capacitive coupling (EC), inductive coupling dominates the total coupling and transmission zeros at the upper stopband are created to steepen the upper skirt of the filtering response.

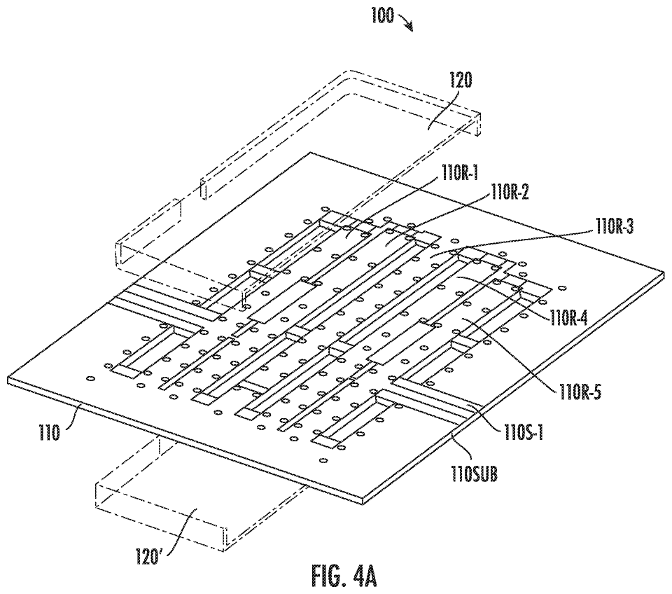

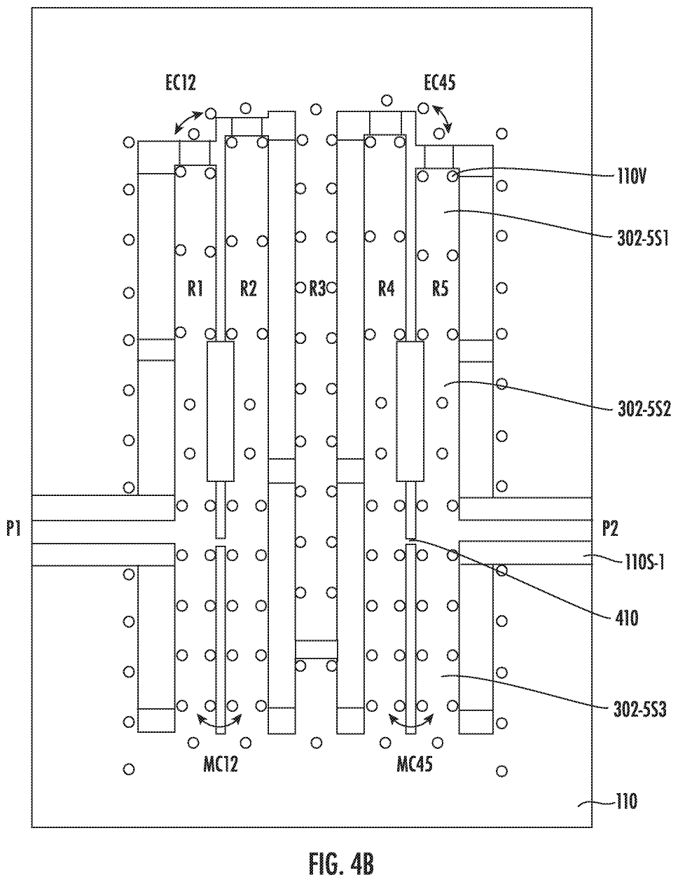

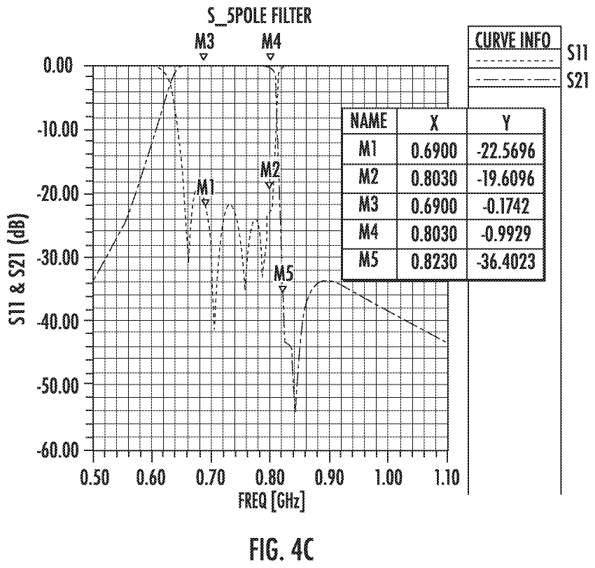

FIGS. 4A and 4B are views of a filter 100 including digital and interdigital resonators 110R according to embodiments of the present inventive concepts. As shown in FIG. 4A, the resonators 110R may include five resonators 110R-1, 110R-2, 110R-3, 110R-4, and 110R-5 that are on a PCB 110 of the filter 100. FIG. 4B illustrates an enlarged top view of the PCB 110 of FIG. 4A. In some embodiments, the resonators 110R shown in FIGS. 4A and 4B may be on a non-PCB substrate 110SUB rather than on the PCB 110.

For simplicity of illustration, the resonators 110R-1, 110R-2, 110R-3, 110R-4, and 110R-5 may be denoted herein as “R1,” “R2,” “R3,” “R4,” and “R5,” respectively. The resonators R1-R5, which provide a five-pole mixed digital and interdigital filter, may be electrically coupled to a resonator layer 110RL′ (FIGS. 1B and 1C) on the opposite, second side 110-S2 of the substrate 110SUB by metallized vias 110V.

As shown in FIG. 4B, resonators R1 and R2 are one pair of adjacent digital resonators, and resonators R4 and R5 are another pair of adjacent digital resonators. Moreover, resonator R3 interdigitates between resonators R2 and R4. Accordingly, the resonators R2 and R3 are one interdigital resonator pair, and the resonators R3 and R4 are another interdigital resonator pair. The term “interdigital resonator pair,” as used herein, thus refers to two resonators R that are laterally next to each other (without another resonator R therebetween) but extend from (i.e., have shorting ends on) opposite ends of the substrate 110SUB.

In some embodiments, one or more of the resonators R1-R5 may include multiple sections, at least one of which has a width different from that of the other sections. For example, the open-end sections of resonators R1 (or R4) and R2 (or R5) can be relatively wide and close to each other, and thus can enhance capacitive coupling EC12 (or EC45). As an example, the resonator R5 may include an open-end section 302-551 that may be wider than an intermediate section 302-5S2 of the resonator R5. The presence of vias 110 in the open-end sections can further enhance the capacitive coupling EC12 (or EC45). Moreover, the shorting-end sections of the resonators R1 (or R4) and R2 (or (R4) can be relatively wide and close to each other, and thus can enhance inductive coupling MC12 (or MC45). For example, the resonator R5 may include a shorting-end section 302-553 that may be wider than the intermediate section 302-5S2.

A metal connection line 410, which can be a short Cu line on one or both resonator layers 110RL and 110RL′ (FIGS. 1A-1C), connecting the resonator R1 (or R4) to the resonator R2 (or R5) may further enhance the inductive coupling MC12 (or MC45). Because the metal connection line 410 is significantly shorter and narrower than the resonators R1-R5, it can provide a coupling inductance.

FIG. 4C is a graph illustrating filtering responses of the filter 100 of FIGS. 4A and 4B. As shown in FIG. 4C, the presence of the inductive coupling MC12 and MC45 that are greater than the capacitive coupling EC12 and EC45 can create inductively-dominant coupling and transmission zeros at the upper stopband.

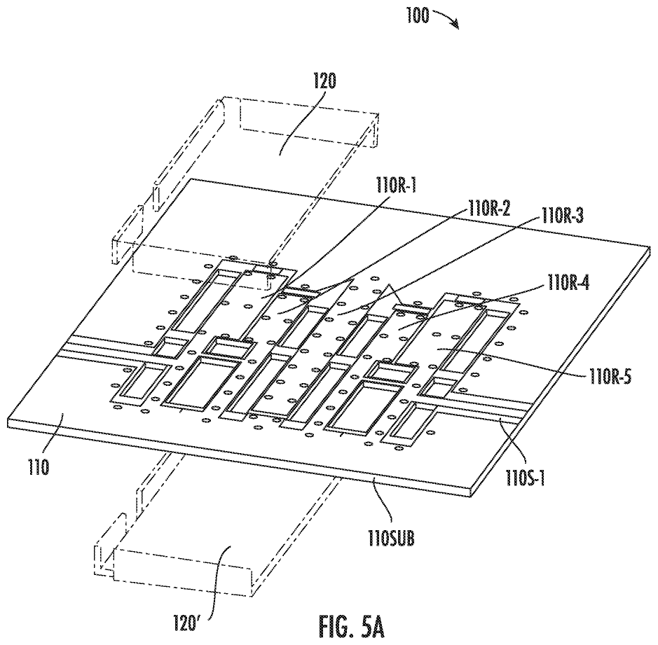

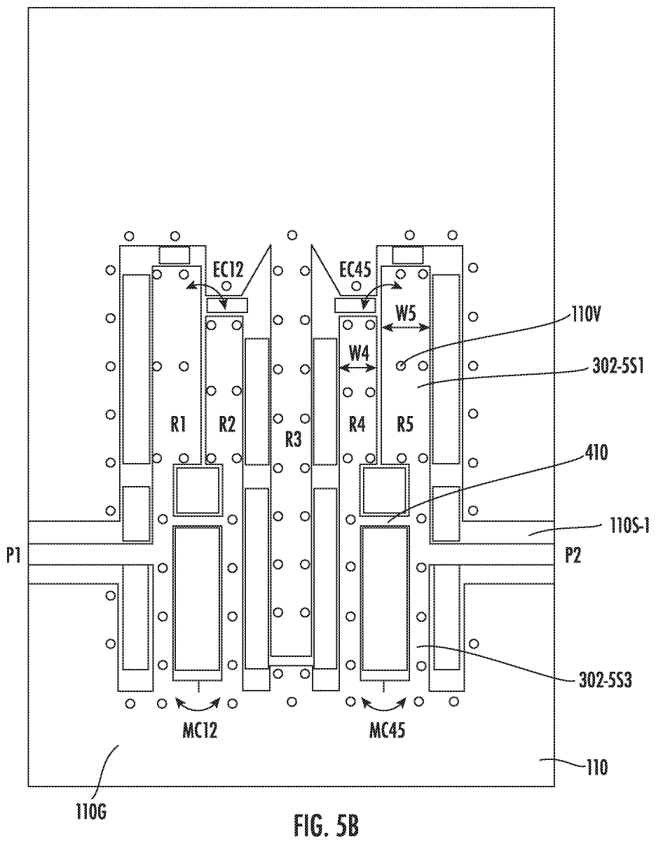

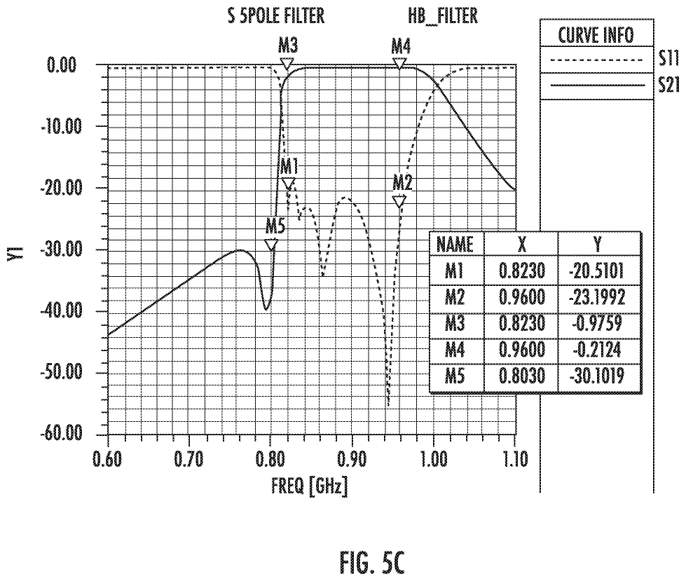

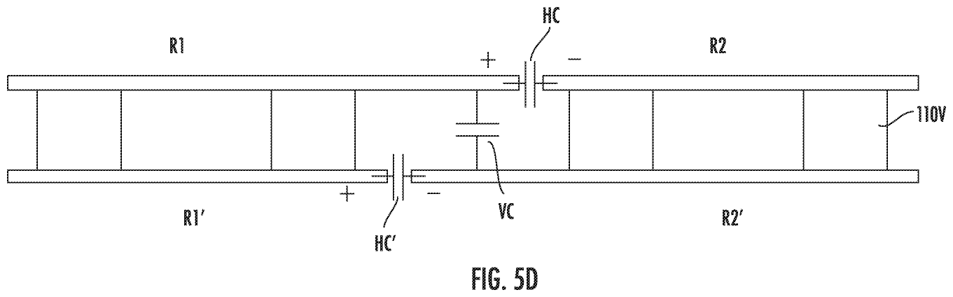

FIGS. 5A and 5B are views of a filter 100 including digital and interdigital resonators according to embodiments of the present inventive concepts. As shown in FIG. 5A, the resonators 110R may include five resonators 110R-1, 110R-2, 110R-3, 110R-4, and 110R-5 that are on a PCB 110 of the filter 100. FIG. 5B illustrates an enlarged top view of the PCB 110 of FIG. 5A. In some embodiments, the resonators 110R shown in FIGS. 5A and 5B may be on a non-PCB substrate 110SUB rather than on the PCB 110. In FIG. 5A, and in some others of the drawings, the metal covers 120 and 120′ are only partially shown.

As with FIG. 4B, the resonators 110R-1, 110R-2, 110R-3, 110R-4, and 110R-5 may be denoted herein as “R1,” “R2,” “R3,” “R4,” and “R5,” respectively, may provide a five-pole mixed digital and interdigital filter, and may be electrically coupled to a resonator layer 110RL′ (FIGS. 1B and 1C) on the opposite, second side 110-S2 of the substrate 110SUB by metallized vias 110V. Relative to FIG. 4B, the shorting-ends of the resonators R1, R2, R4, and R5 in FIG. 5B are narrower and father away from each other. For example, the shorting-end section 302-553 of the resonator R5 may be narrower, and spaced farther from the resonator R4, in FIG. 5B than in FIG. 4B. As a result, the capacitive coupling EC12 and EC45 in FIG. 5B can be greater than the inductive coupling MC12 and MC45. FIG. 5B also shows that a widest width W5 of the resonator R5 may be wider than a widest width W4 of the resonator R4.

FIG. 5C is a graph illustrating filtering responses of the filter 100 of FIGS. 5A and 5B. As shown in FIG. 5C, the capacitively-dominant coupling provided by the structure in FIG. 5B can result in transmission zeros located at the lower stopband.

FIG. 5D is a diagram illustrating capacitances in a filter 100 according to embodiments of the present inventive concepts. In particular, FIG. 5D shows a cross-section along line A-A of the filter 100 of FIG. 5B that includes the resonators R1 and R2. The structure shown in FIGS. 5B and 5D can enhance the capacitive coupling EC12 between the resonators R1 and R2. The capacitive coupling EC45 between the resonators R4 and R5 may be enhanced by using a similar structure to that shown in FIG. 5D. The diagram of FIG. 5D illustrates an example in which RF power is transmitted from the resonator R1 to the resonator R2, the resonator R1 carries positive charge, and the resonator R2 carries negative charge.

In the resonator layer 110RL (FIGS. 1A and 1C), the resonator R1 may be wider than the resonator R2, whereas the resonator R1′ may be narrower than the resonator R2′ in the resonator layer 110RL′ (FIGS. 1B and 1C). The resonators R1 and R1′ can be physically/electrically coupled to each other by one or more metallized vias 110V and/or by metal plating 110EP. Also, the resonators R2 and R2′ can be physically/electrically coupled to each other by one or more metallized vias 110V and/or by metal plating 110EP. The horizontal gap between the resonators R1 and R2 creates a horizontal capacitance HC, and the overlap of the resonators R1 and R2′ shown in FIG. 5D creates a vertical capacitance VC. Similarly, the horizontal gap between the resonators R1′ and R2′ creates a horizontal capacitance HC′. The horizontal and vertical capacitances combine to provide a very strong capacitive coupling EC12.

The resonators R1 and R2′ may vertically overlap because the resonator R1 may be wider, in a direction perpendicular to the vertical capacitance VC, than the resonator R2 and the resonator R1′. The resonator R2′ may also be wider than the resonator R2 and the resonator R′. The entire length of the resonator R2 may overlap the resonator R2′, whereas only a portion of the resonator R1 may overlap the resonator R2′. Another portion of the resonator R1 may overlap the resonator R′. The portion of the resonator R1 that overlaps the resonator R2′ comprises a vertical capacitive coupling (the vertical capacitance VC) to the resonator R2′.

FIGS. 6A-6C are views of a diplexer 100D including a metal junction 610 (FIG. 6C) according to embodiments of the present inventive concepts. The diplexer 100D is one example of a filter 100. The filters 100 described herein, however, are not limited to diplexers 100D. Also, though FIGS. 6A-6C illustrate a PCB diplexer 100D that comprises a PCB 110D, some embodiments may provide a non-PCB diplexer 100D that comprises a non-PCB substrate 110SUB.

The diplexer 100D of FIGS. 6A-6C may be provided by combining the filters 100 of FIGS. 4A and 5A. For example, FIG. 6A illustrates an exploded top perspective view of the diplexer 100D, in which the resonators 110R of the filter 100 of FIG. 4A may be on a left region of the first side 110S-1 of the substrate 110SUB, and the resonators 110R of the filter 100 of FIG. 5A may be on a right region of the first side 110S-1. To distinguish between the resonators 110R of the filter 100 of FIG. 4A and the resonators 110R of the filter 100 of FIG. 5A, the resonators 110R of the filter 100 of FIG. 5A may be denoted as resonators 110R-D when present in a diplexer 100D. As an example, the resonators 110R-D may include five resonators 110R-1D, 110R-2D, 110R-3D, 110R-4D, and 110R-5D (FIG. 6C). Moreover, though the diplexer 100D of FIG. 6A comprises the resonators 110R and the resonators 110R-D on left and right regions, respectively, of the first side 110S-1 of the substrate 110SUB, they may alternatively be on right and left regions, respectively, of the first side 110S-1.

The resonators 110R and the resonators 110R-D may provide first and second filters 110F-1 and 110F-2, respectively, of a diplexer 100D. As shown in FIG. 6B, which illustrates an exploded bottom perspective view of the diplexer 100D, the first filter 110F-1 may further comprise resonators 110R′ on the second side 110S-2 of the substrate 110SUB, and the second filter 110F-2 may further comprise resonators 110R-D′ on the second side 110S-2. The resonators 110R and the resonators 110R′ of the first filter 110F-1 may be electrically coupled to each other by one or more metallized vias 110V (FIG. 6C) and/or by metal plating 110EP (FIGS. 6K and 6M). Similarly, the resonators 110R-D and the resonators 110R-D′ of the second filter 110F-2 may be electrically coupled to each other by one or more metallized vias 110V and/or by metal plating 110EP.

FIG. 6C is an enlarged top view of the diplexer 100D of FIGS. 6A and 6B. As shown in FIG. 6C, the first and second filters 110F-1 and 110F-2 may be combined with each other through a metal junction 610 to provide the diplexer 100D. The metal junction 610 connects the first and second filters 110F-1 and 110F-2 to a common port P1 that is shared by the first and second filters 110F-1 and 110F-2. As the first and second filters 110F-1 and 110F-2 are connected to respective ports P2 and P3 that are on opposite ends/edges of the substrate 110SUB, and as the common port P1 is on yet another end/edge of the substrate 110SUB, the ports P1-P3 may be arranged in a T-shape and the metal junction 610 that connects the first and second filters 110F-1 and 110F-2 to the common port P1 may thus be referred to herein as a “T-junction.”

FIG. 6D is a graph illustrating filtering responses of the diplexer 100D of FIGS. 6A-6C. To implement a wideband response, such as 823 MHz˜960 MHz and fractional bandwidth (FBW)>10%, small gaps (<3% λ, where λ represents a wavelength in air corresponding to the center frequency of the operating frequency band of the diplexer 100D) between resonators 110R/110R-D may be used to create sufficiently strong coupling, which can cause electric field breakdown across air under high power input.

FIG. 6E is a top view of a diplexer 100D including a common resonator 110R-C according to embodiments of the present inventive concepts. The diplexer 100D of FIG. 6E is provided by combining the first and second filters 110F-1 and 110F-2 through the common resonator 110R-C. Accordingly, the common resonator 110R-C, which is shared by the first and second filters 110F-1 and 110F-2, may be an alternative to the metal junction 610 of FIG. 6C. As shown in FIG. 6E, a feeding line 635 that extends from the common port P1 is coupled to the common resonator 110R-C through both horizontal and vertical capacitances, thus providing strong coupling.

FIGS. 6F-6H are views of a diplexer 100D including a solder mask 611 according to embodiments of the present inventive concepts. In particular, FIGS. 6F and 6G are top and bottom views, respectively, of the diplexer 100D including the solder mask 611, and FIG. 6H is an enlarged view of a portion of FIG. 6F that includes the solder mask 611.

The solder mask 611 may be a thin non-metallic (e.g., lacquer-like) substance that, for protective purposes, is coated onto one or more areas on the substrate 110SUB where high power arc discharge (electrical breakdown through an insulator, such as air) is likely to occur. Specifically, the solder mask 611, though it may increase electrical loss, may inhibit/prevent high power arc discharge at one or more high voltage points, such as regions where adjacent ones of the resonators 110R are very close together. As an example, the solder mask 611 may be between the resonators 110R-1D and 110R-2D of a digital resonator pair and/or between the resonators 110R-4D and 110R-5D of another digital resonator pair. In some embodiments, the solder mask 611 may overlap a portion of the resonator 110R-1D and a portion of the resonator 110R-2D, and/or may overlap a portion of the resonator 110R-4D and a portion of the resonator 110R-5D.

FIG. 6F also illustrates that the diplexer 100D may include an embedded resonator 110R-3DE, which may be embedded within one (e.g., the resonator 110R-3D) of the resonators 110R/110R-D of the diplexer 100D. The embedded resonator 110R-3DE may improve guard band isolation. In some embodiments, the embedded resonator 110R-3DE and the solder mask 611 may both be included in the diplexer 100D, which may be a PCB diplexer. Alternatively, the diplexer 100D may include the embedded resonator 110R-3DE but not the solder mask 611, or vice versa.

FIG. 60 further illustrates that the solder mask 611 and an embedded resonator 110R-3DE′ may be on the second side 110S-2 of the substrate 110SUB of the diplexer 100D. A resonator 110R-3D′ that comprises the embedded resonator 110R-3DE′ therein may be electrically coupled to the resonator 110R-3D that comprises the embedded resonator 110R-3DE therein by one or more metallized vias 110V and/or by metal plating 110EP (FIGS. 6K and 6M).

FIG. 6I is a graph illustrating filtering responses of the diplexer 100D of FIGS. 6F-6H. In FIG. 6I, isolation at 0.803 GHz is improved relative to FIG. 6D from 26 dB to 29 dB. The embedded resonator 110R-3DE introduces an additional transmission zero at the lower stopband of the high-band filter S31. In particular, the embedded resonator 110R-3DE may introduce both an additional transmission pole and the additional transmission zero. It may not be desirable to include more than one embedded resonator in the diplexer 100D, however, because the presence of multiple embedded resonators can be harmful with respect to tuning the filter 110F-2. Fine tuning the embedded resonator 110R-3DE can improve isolation, whereas de-tuning the embedded resonator 110R-3DE can cause destructive RF performance. Moreover, the embedded resonator 110R-3DE and the embedded resonator 110R-3DE′ can operate as a single embedded resonator due to their vertical connection to each other, and thus can introduce the additional transmission pole and the additional transmission zero without harming tuning.

The embedded resonator 110R-3DE and the embedded resonator 110R-3DE′ can be physically connected at their shorting ends, and may have no vertical connection at locations other than the shorting ends. Because the embedded resonators 110R-3DE and 110R-3DE′ are thin in a horizontal width direction, the embedded resonators 110R-3DE and 110R-3DE′ may, in some embodiments, save space by not being vertically connected to each other. For example, the embedded resonators 110R-3DE and 110R-3DE′ may be narrower than a PTH via. Moreover, extracting substrate material to allow for sidewall plating in a slot surrounding the embedded resonators 110R-3DE and 110R-3DE′ may weaken mechanical support to the embedded resonators 110R-3DE and 110R-3DE′. The quarter wavelength long embedded resonator 110R-3DE can also be perceived as a half-wavelength long slot. The voltage drop across the slot between the embedded resonator 110R-3DE and another/outer portion of the resonator 110R-3D is the dominant voltage drop. Moreover, the other/outer portion of resonator 110R-3D may be electrically coupled vertically with another/outer portion of the resonator 110R-3D′. Accordingly, even without a vertical metal connection between the embedded resonators 110R-3DE and 110R-3DE′, the embedded resonator 110R-3DE may share the same voltage potential with the embedded resonator 110R-3DE′.

FIGS. 6J and 6K are views of PCB sidewalls 110SW of filters 100 according to embodiments of the present inventive concepts. FIG. 6J is an enlarged view of a portion of the filter 110F-2 of FIG. 6F that includes the resonators 110R-1D and 110R-2D. One example of a sidewall 110SW is a bare (e.g., un-plated) sidewall/edge 110BE of a portion of the substrate 110SUB that is between the resonator 110R-1D and the resonator 110R-1D′ (FIG. 6G). Edge current flowing along the resonator 110R-1D and the resonator 1OR-1D′ may have a significantly higher density than that of a 50-Ohm microstrip transmission line, due to their resonating effect. Such high edge current may be undesirable.

In comparison with FIG. 6J, FIG. 6K shows that a sidewall 110SW can be plated/metallized with metal plating 110EP that extends to vertically connect the resonator 110R-1D and the resonator 110R-1D′ to each other. The metal plating 110EP may advantageously reduce current density along the resonator 110R-1D and the resonator 110R-1D′. Though FIG. 6K illustrates an example in which the metal plating 110EP is on one sidewall 110SW of an opening 602 in the substrate 110SUB that is between the resonator 110R-1D and the resonator 110R-2D, the metal plating 110EP may additionally or alternatively be on an opposite sidewall of the opening 602 and/or on a sidewall of another opening in the substrate 110SUB. For example, the metal plating 110EP may be located at a plurality of high-current regions of the substrate 110SUB. The reduced current density that results from the metal plating 110EP may also reduce PIM and increase power handling.

Moreover, the metal plating 110EP can be applied to the substrate 100SUB of any of the filters 100 described herein, and is not limited to the diplexer 100D of FIG. 6F. As an example, the metal plating 110EP may extend vertically on a sidewall of an opening in the substrate 110SUB that is between the resonator 110R-4 and the resonator 110R-5 (FIG. 4A) of a digital resonator pair to electrically connect the resonator layer 110RL to the resonator layer 110RL′ (FIG. 1C).

FIGS. 6L and 6M are views of a diplexer 100D including plated sidewalls 110EP according to embodiments of the present inventive concepts. In particular, FIG. 6L is a top perspective view of the diplexer 100D, and FIG. 6M is an enlarged view of a portion of the diplexer 100D of FIG. 6L that includes the resonator 110R-4D and the resonator 110R-5D. The substrate 110SUB may include openings 602 and 603 therein, which may also be referred to herein as “cutouts” from the substrate 110SUB. The openings 602 are between adjacent resonators 110R/110R-D of a digital resonator pair, and the openings 603 are between the resonators 110R/110R-D and adjacent non-resonator portions of the substrate 110SUB. One or more of the openings 602 and/or one or more of the openings 603 may have metal-plated sidewalls 110EP.

The substrate 110SUB may also have one or more non-plated through-holes (NPTHs) 620 that extend through the substrate 110SUB and are free of the metal plating 110EP. Specifically, the metal plating 110EP may be on sidewalls 110SW of the openings 602/603 but absent from the NPTHs 620, which may be recessed/cavity portions in the sidewalls 110SW. Accordingly, the NPTHs 620 provide discontinuities in the metal plating 110EP that is on the sidewalls 110SW.

The NPTHs 620 thus advantageously disconnect undesirable connections that may otherwise be present due to the metal plating 110EP. For example, the metal plating 110EP may undesirably short circuit adjacent resonators 110R/110R-D to each other, and/or may undesirably short circuit one of the resonators 110R/110R-D to ground 110G. The NPTHs 620, however, can inhibit such short-circuit points by providing discontinuities in the metal plating 110EP. In some embodiments, one or more of the NPTHs 620 may be at curved/corner locations of the openings 602/603.

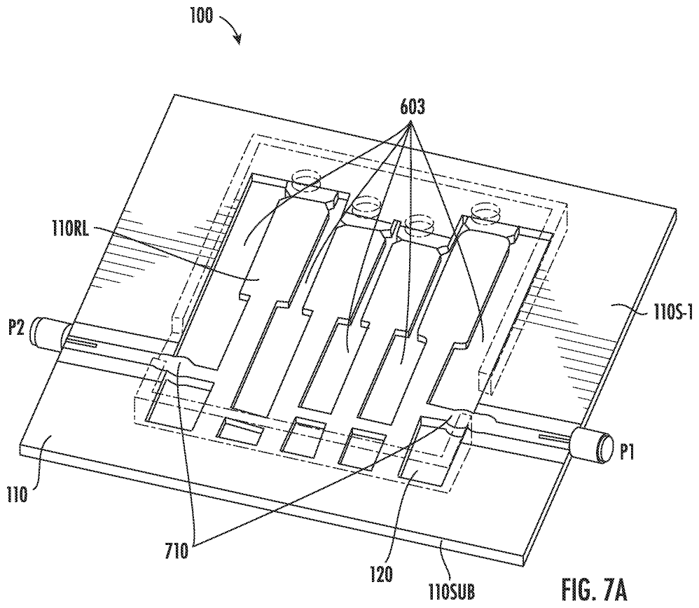

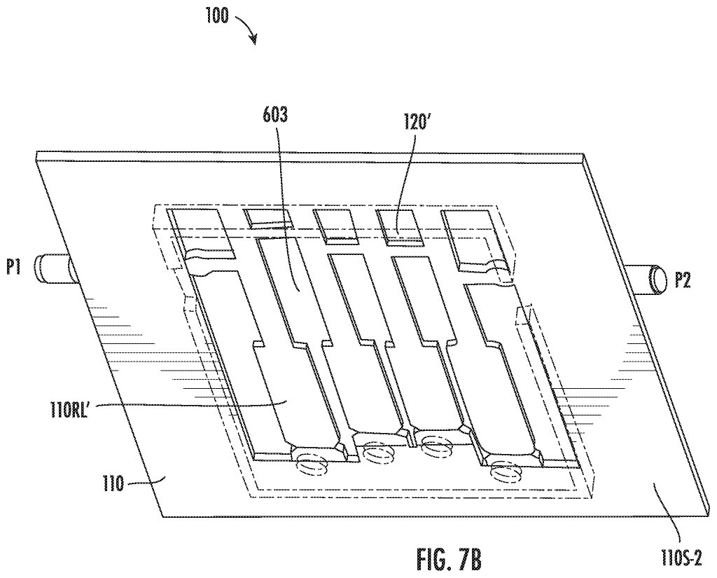

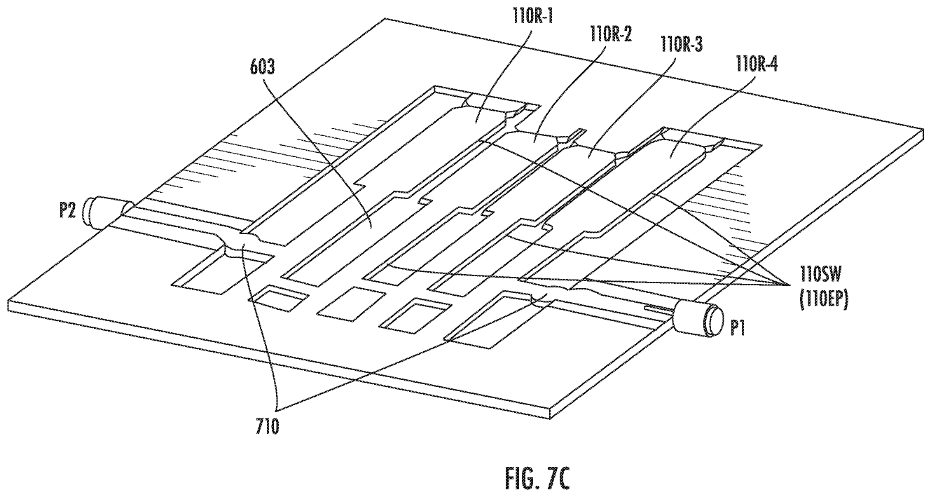

FIGS. 7A-7C are views of a filter 100 according to embodiments of the present inventive concepts. FIG. 7A is a top view of the filter 100, FIG. 7B is a bottom view of the filter 100, and FIG. 7C is a top perspective view of the filter 100. In particular, FIG. 7C is a simplified view of a portion of FIG. 7A and is angled to show metal plating 110EP on sidewalls 110SW of resonators 110R, including resonators 110R-1, 110R-2, 110R-3, and 110R-4. In this simplified view in FIG. 7C, the metal cover 120, which is shown translucently in FIG. 7A to obscure only portions of the underlying structure, is omitted. FIG. 7C also illustrates microstrip-to-strip transitions 710.

As shown in FIG. 7C, each of the resonators 110R-1, 110R-2, 110R-3, and 110R-4 may have the metal plating 110EP on the sidewalls 110SW thereof in large openings (e.g., cutouts) 603 that extend between the resonators 110R-1, 110R-2, 110R-3, and 110R-4. Moreover, the resonators 110R-1, 110R-2, 110R-3, and 110R-4 may each be free of any metallized (e.g., plated) via, such as the PTH vias 210V. Accordingly, no metallized via may penetrate a surface (e.g., a top surface) of any of the resonators 110R-1, 110R-2, 110R-3, and 110R-4.

The filter 100 of FIGS. 7A-7C may thus provide improved PIM performance, due to (a) the presence of the large metal-plated openings 603 between the resonators 110R and 110R′ and/or (b) the omission of plated vias in the resonators 110R and 1OR′. For example, the omission of plated vias in one or more of the first resonator layer 110RL, including the resonators 110R-1, 110R-2, 110R-3, and 110R-4, and the second resonator layer 110RL′ may reduce the number of sharp copper edges, and thus may provide lower current density and a better PIM level.

In some embodiments, a substrate 110SUB can include one or more other RF components, in addition to a filter 100. For example, the substrate 110SUB may include one or more phase shifters, such as phase shifter(s) for a base station antenna. Example phase shifters are discussed in U.S. Pat. No. 7,907,096 to Timofeev, the disclosure of which is hereby incorporated herein by reference in its entirety. Both the filter 100 and the phase shifter(s) may be, as an example, printed on the same PCB 110. In some embodiments, the filter 100 may be integrated with a feed board that is electrically coupled to the phase shifter(s).

A filter 100 according to embodiments of the present inventive concepts may provide a number of advantages. These advantages include increasing the Q-factor (e.g., from about 100 to about 1000) by decreasing the current density on the resonators 110R and 110R′. For example, in comparison with having resonators on only a single side of a device, the combination of the resonators 110R and 110R′ on the first and second sides 110S-1 and 110S-2, respectively, provides a double-sided filter 100 having increased resonator surface area, which can reduce current density and increase power handling capability.

In some embodiments, further advantages may be provided by cutting out portions of the substrate 110SUB adjacent the resonators 110R and 110R′ to provide openings 202/602/603. The openings 202/602/603 not only reduce dielectric loss, but also provide sidewalls 110SW that can be metallized to electrically connect the resonators 110R and 110R′ of the double-sided resonator structure. Metallizing (with metal plating 110EP) the sidewalls 110SW of the filter 100 can help to further reduce current density, particularly at high current density locations along the edges of the resonators 110R and 110R′.

One reason the double-sided resonator structure of the filter 100 improves excessive current density is because the combination of the resonators 110R and 110R′ reduces current density along rough surfaces (e.g., surfaces facing the substrate 110SUB) of the resonators 110R and 110R′. Because the metallized vias 110V (and/or or metal plating 110EP) keep both sides of the double-sided resonator structure at substantially the same electric potential, currents tend to stay on the outer surfaces of the resonators 110R and 110R′ rather than on the rough surfaces that are opposite the outer surfaces.

Edges of the resonators 110R and 110R′ may be high current density areas. They also tend to be rough. Metallizing the sidewalls 110SW of the substrate 110SUB to electrically connect the resonators 110R and 110R′ to each other, however, can reduce current density along the edges, and may also reduce surface roughness. This reduces ohmic loss and improves PIM performance. The metallized sidewalls 110SW may also advantageously provide increased horizontal capacitive coupling between adjacent resonators 110R/110R′.

The reduced current flow along interfaces between the substrate 110SUB and the resonators 110R and 110R′ can also reduce ohmic loss. Moreover, the increased thickness of the double-sided resonator structure relative to a single-sided resonator structure can further reduce ohmic loss by reducing overall current density.

In addition to reducing current density and reducing ohmic loss, the double-sided resonator structure can reduce dielectric loss by reducing electrical fields through the substrate 110SUB. The electrical fields are reduced because the resonators 110R and 110R′ on opposite sides 110S-1 and 110S-2, respectively, of the substrate 110SUB are electrically-coupled to each other, and thus are at substantially the same electric potential.

In some embodiments, the substrate 110SUB may be a substrate of a PCB 110. By using portions of the PCB 110 as the resonators 110R and 110R′, the filter 100 may have a lower weight and a lower cost than a conventional fully-mechanical filter that uses die-cast resonators. For example, in embodiments in which the resonators 110R and 110R′ are PCB resonators, the filter 100 may cost less than a conventional fully-mechanical filter, due to better integration and decreased tuning efforts with the filter 100. The filter 100 can thus provide a low-cost filter, which can be used in systems/apparatuses such as a base station antenna.

The present inventive concepts have been described above with reference to the accompanying drawings. The present inventive concepts are not limited to the illustrated embodiments. Rather, these embodiments are intended to fully and completely disclose the present inventive concepts to those skilled in this art. In the drawings, like numbers refer to like elements throughout. Thicknesses and dimensions of some components may be exaggerated for clarity.

Spatially relative terms, such as “under,” “below,” “lower,” “over,” “upper,” “top,” “bottom,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” or “beneath” other elements or features would then be oriented “over” the other elements or features. Thus, the example term “under” can encompass both an orientation of over and under. The device may be otherwise oriented (rotated 90 degrees or at other orientations) and the spatially relative descriptors used herein interpreted accordingly.

Herein, the terms “attached,” “connected,” “interconnected,” “contacting,” “mounted,” and the like can mean either direct or indirect attachment or contact between elements, unless stated otherwise.

Well-known functions or constructions may not be described in detail for brevity and/or clarity. As used herein the expression “and/or” includes any and all combinations of one or more of the associated listed items.

The terminology used herein is for the purpose of describing particular embodiments only and is not intended to be limiting of the present inventive concepts. As used herein, the singular forms “a,” “an,” and “the” are intended to include the plural forms as well, unless the context clearly indicates otherwise. It will be further understood that the terms “comprises,” “comprising,” “includes,” and/or “including” when used in this specification, specify the presence of stated features, operations, elements, and/or components, but do not preclude the presence or addition of one or more other features, operations, elements, components, and/or groups thereof.

1. A multi-pole filter comprising:
a substrate;
first and second resonators on a first side of the substrate;
third and fourth resonators on a second side of the substrate that is opposite the first side of the substrate;
a first vertical connection that extends vertically from the first side of the substrate to the second side of the substrate, to electrically connect the first resonator to the third resonator;
a second vertical connection that extends vertically from the first side of the substrate to the second side of the substrate, to electrically connect the second resonator to the fourth resonator; and
an opening in the substrate between the first resonator and the second resonator,
wherein the first vertical connection comprises metal plating that extends vertically on a sidewall of the opening to electrically connect the first resonator to the third resonator.

2. The multi-pole filter of claim 1,
wherein the opening extends through the substrate between respective first portions of the first and second resonators that are narrower than respective second portions of the first and second resonators, and between respective first portions of the third and fourth resonators that are narrower than respective second portions of the third and fourth resonators,
wherein the multi-pole filter further comprises a first metallized via that electrically connects the first resonator and the third resonator to each other, and
wherein the second vertical connection comprises a second metallized via that electrically connects the second resonator and the fourth resonator to each other.

3. The multi-pole filter of claim 1, further comprising:
a first metal cover over the first and second resonators on the first side of the substrate; and
a second metal cover over the third and fourth resonators on the second side of the substrate.

4. The multi-pole filter of claim 1,
wherein the substrate comprises a substrate of a first printed circuit board (PCB), and
wherein the multi-pole filter further comprises:
second and third PCBs on the first side of the substrate of the first PCB; and
fourth and fifth PCBs on the second side of the substrate of the first PCB.

5. The multi-pole filter of claim 4,
wherein the second PCB is between the first and third PCBs and comprises a first opening,
wherein the fourth PCB is between the first and fifth PCBs and comprises a second opening, and
wherein the second and fourth PCBs each comprise metallized sidewalls.

6. The multi-pole filter of claim 4, further comprising:
a screw that connects the second and third PCBs to each other.

7. The multi-pole filter of claim 4, further comprising:
a pre-preg that connects the second and third PCBs to each other,
wherein the multi-pole filter further comprises a first metallized via that electrically connects the first resonator and the third resonator to each other,
wherein the second vertical connection comprises a second metallized via,
wherein the multi-pole filter further comprises a third metallized via that electrically connects the first and second PCBs to each other, and
wherein the second PCB comprises an opening that extends to an outer edge of the second PCB.

8. The multi-pole filter of claim 1, further comprising:
a fifth resonator on the first side of the substrate, wherein the first, second, and fifth resonators are tapered toward respective first, second, and third openings in the substrate,
wherein the fifth resonator comprises different first, second, and third widths.

9. (canceled)

10. The multi-pole filter of claim 1,
wherein the first and second resonators are among a first plurality of resonators on the first side of the substrate,
wherein the first plurality of resonators comprises a pair of digital resonators and a pair of interdigital resonators, and
wherein the third and fourth resonators are among a second plurality of resonators on the second side of the substrate.

11. The multi-pole filter of claim 10, wherein a first and a second of the pair of digital resonators are connected to each other by a metal connection line.

12. The multi-pole filter of claim 11, wherein a widest width of the first of the pair of digital resonators is wider than a widest width of the second of the pair of digital resonators.

13. The multi-pole filter of claim 12, further comprising a third plurality of resonators on the first side of the substrate,
wherein the first and third pluralities of resonators comprise first and second filters, respectively, of a diplexer.

14. The multi-pole filter of claim 13, further comprising a metal junction that connects the first and second filters to a common port.

15. The multi-pole filter of claim 13, further comprising a common resonator that is coupled to a common port of the first and second filters.

16. The multi-pole filter of claim 1, further comprising a solder mask that is between the first resonator and the second resonator.

17. The multi-pole filter of claim 1, wherein the sidewall of the opening comprises a non-plated through-hole that is free of the metal plating.

18. The multi-pole filter of claim 1, wherein an embedded resonator is within the second resonator.

19. The multi-pole filter of claim 1,
wherein the first resonator is wider than the second resonator and wider than the third resonator,
wherein an entirety of the second resonator overlaps the fourth resonator, and
wherein a portion of the first resonator overlaps the fourth resonator.

20-29. (canceled)

30. A multi-pole filter comprising a substrate comprising a first resonator layer on a first side of the substrate and a second resonator layer that is electrically coupled to the first resonator layer and is on a second side of the substrate that is opposite the first side of the substrate,
wherein the first resonator layer comprises adjacent first and second resonators that are capacitively coupled to each other across a horizontal gap therebetween,
wherein the second resonator layer comprises adjacent third and fourth resonators that are capacitively coupled to each other across a horizontal gap therebetween,
wherein the first resonator overlaps the third resonator, and
wherein the first and second resonators both overlap the fourth resonator.

31. The multi-pole filter of claim 30,
wherein the first resonator is wider than the second resonator and wider than the third resonator,
wherein an entirety of the second resonator overlaps the fourth resonator,
wherein only a portion of the first resonator overlaps the fourth resonator, and
wherein the portion of the first resonator comprises a vertical capacitive coupling to the fourth resonator.
